(19) United States
(12) Patent Application Publication
(10) Pub. No.: US 2022/0143748 A1
(43) Pub. Date: May 12, 2022

(54) LASER SURFACE PROCESSING SYSTEMS AND METHODS FOR PRODUCING NEAR PERFECT HEMISPHERICAL EMISSIVITY IN METALLIC SURFACES

(71) Applicant: NUtech Ventures, Lincoln, NE (US)

(72) Inventors: Andrew R. Reicks, Lincoln, NE (US); Craig Zuhlke, Lincoln, NE (US); Alfred Tooru Tsubaki, Lincoln, NE (US); Christos Argyropoulos, Lincoln, NE (US); George Gogos, Lincoln, NE (US); Mark Anderson, Lincoln, NE (US); Dennis R. Alexander, Lincoln, NE (US)

(21) Appl. No.: 17/525,094

(22) Filed: Nov. 12, 2021

Related U.S. Application Data
(60) Provisional application No. 63/112,932, filed on Nov. 12, 2020.

(51) Int. Cl. B23K 26/0622; B23K 26/352; B23K 26/12

(52) U.S. Cl. CPC B23K 26/0624; B23K 26/123; B23K 26/352

(57) ABSTRACT

A method for laser-processing a metallic surface to produce a functionalized metallic surface comprises: providing a substrate having the metallic surface; applying a pulsed laser beam with a controlled fluence to a region of the metallic surface in an environment containing oxygen, wherein metal material in the region of the metallic surface ablates due to the applied pulsed laser beam and wherein at least a portion of the ablated metal material oxidizes and redeposits on the metallic surface to produce one or more oxidized-metal-coated structures; wherein the metallic surface having the one or more oxidized-metal-coated structures is the functionalized metallic surface. Optionally, the functionalized metallic surface has a higher hemispherical emissivity than the metallic surface free of the oxidized-metal-coated structures and prior to applying the pulsed laser beam under otherwise identical conditions. Optionally, the functionalized metallic surface is characterized by a hemispherical emissivity of at least 0.85.

### CROSS-REFERENCE TO RELATED APPLICATIONS

This application claims the benefit of priority to U.S. Provisional Patent Application No. 63/112,932, filed Nov. 12, 2020, which is hereby incorporated by reference in its entirety.

### STATEMENT REGARDING FEDERALLY SPONSORED RESEARCH OR DEVELOPMENT

This invention was made with government support under N00014-19-1-2384 awarded by the Office of Naval Research and under NNX15AI09H awarded by the National Aeronautics and Space Administration. The government has certain rights in the invention.

### BACKGROUND

Recently, a substantial amount of research efforts have focused on developing surfaces with high electromagnetic absorption or emission in the infrared (IR) regions of the electromagnetic spectrum with important applications in passive radiative cooling, thermophotovoltaics, and thermal management of spacecraft. Typically, state-of-the-art surfaces with high electromagnetic absorption/emission can be divided into three categories: coatings and paints; metamaterials; and laser processed surfaces.

Coatings and paints are similar approaches to increasing emissivity; they are utilized to add a layer or layers of a material to a substrate to obtain surface properties different than those of the substrate. Coating and paint technologies vary significantly in terms of materials, thickness, number of layers, and application method. Coatings are usually designed to utilize the emission properties of a low index material and the high absorption caused by the phonon-polariton resonance of a high index material at IR frequencies. Paints can vary significantly on how the high emissivity response is achieved, however, many are based on organic compounds or oxide nanoparticles. Coatings and paints have a number of advantages including the relative ease and affordability in which they can be applied to nearly any material, which has led to their widespread usage. Additionally, several coatings and paints offer tunable absorption over most of the IR spectrum, however these are typically narrowband. Coatings and paints have similar disadvantages including being prone to delamination and easy degradation over time, especially in harsh environments such as space. Since they are relatively smooth, most suffer from high angular sensitivity. Additionally, most high-emissivity coatings or paints require time to fully cure before they can be used, usually up to seven days, and utilize toxic materials.

Recently, wide-angle, high absorption/emission responses have been demonstrated with metallic (plasmonic) or dielectric metamaterial structures. It has also been demonstrated that metallic gratings can be used to produce near perfect emissivity at a chosen wavelength and angle. Similarly, tapered and elongated gratings can offer near perfect absorption across several angles in the visible spectrum. Narrowband absorption in the IR spectrum has also been demonstrated by using different surface shapes, such as crosses, circles, and squares. Using other shapes like “trapezoidal ridges” offers absorption over a broader spectral band, and the use of grids offers high absorption at a wide range of angles. However, all of these structures result in enhanced absorption/emission over a narrow spectral band, typically over just a few micrometers. In addition, their response is angle-dependent, and they do not operate as perfect absorbers at grazing angles. Recently, theoretical works have demonstrated tunable, near-perfect, wide-angle absorption over a variety of wavelength ranges in the IR spectrum by using alternating metal-dielectric layers and metamaterials with different surface shapes such as columns, pyramids, or trapezoidal structures. Nevertheless, the experimental verification of these structures is still elusive, mainly due to the complexity of the required niche fabrication processes. Moreover, most applications of high emissivity surfaces require large area inexpensive absorbers, while most metamaterial structures can currently only be produced over extremely small areas using costly high accuracy lithographic techniques. In addition, the perfectly periodic nature required of these metamaterials is prone to fabrication imperfections, so typically high emissivity is obtained for only a narrow spectral range as compared to the broadband results that have been demonstrated using coatings.

Many previous studies have demonstrated that laser processing can be used to modify how surfaces reflect, absorb, or emit light, including large increases in broadband absorption/emission on surfaces processed using short pulsed lasers. Broadband moderate absorption values have been demonstrated over a wide spectral range from 0.3 to 50 μm on aluminum processed using a femtosecond laser at relatively high fluence (7 J/cm²). Periodic ripples produced using low fluence values, known as laser induced period surface structures (LIPSS), can be used to produce high absorption in narrow bands that are tunable over a wide spectral range from 250 nm to 300 μm on aluminum, very similar to the results demonstrated for metamaterial structures. Research on LIPSS has been expanded up to fluence values of 2.4 J/cm² with similar results in a narrower spectral band of 0.4 to 1 μm. Another study of laser processed surfaces demonstrated similar high absorption results from 2.5 to 15 μm, but achieved only for angles of 10, 40, and 60 degrees from the surface normal. Previous works reported in the literature have indicated that the increase in broadband absorption of the laser processed material is only caused by micro and nanoscale surface structures. While this may be the case for noble metals like platinum, the previous studies on other earth-abundant and cheaper metals, such as aluminum, have neglected the effect of the surface oxide layer.

Accordingly, it is desirable to provide improved techniques for developing surfaces with high electromagnetic absorption or emission.

### SUMMARY

The present embodiments provide functionalized surfaces with excellent to near perfect absorption/emission that is broadband and omnidirectional as well as scalable processes for manufacturing or forming such surfaces. Certain embodiments advantageously leverage the role that an oxide layer contributes to modifying surface properties.

Aspects disclosed herein include a method for laser-processing a metallic surface to produce a functionalized metallic surface, the method comprising: providing a substrate having the metallic surface; applying a pulsed laser beam with a controlled fluence to a region of the metallic surface in an environment containing oxygen, wherein metal material in the region of the metallic surface ablates due to the applied pulsed laser beam and wherein at least a portion of the ablated metal material oxidizes and redeposits on the metallic surface to produce one or more oxidized-metal-coated structures; wherein the metallic surface having the one or more oxidized-metal-coated structures is the functionalized metallic surface. Preferably, the functionalized metallic surface has a higher hemispherical emissivity than the metallic surface free of the oxidized-metal-coated structures and prior to applying the pulsed laser beam under otherwise identical conditions. Preferably, but not necessarily, the functionalized metallic surface has a 15% to 1200%, optionally 25% to 1200%, optionally 50% to 1200%, optionally 75% to 1200%, optionally 100% to at least 1200%, optionally 15% to at least 1500%, higher hemispherical emissivity than the metallic surface free of the oxidized-metal-coated structures and prior to applying the pulsed laser beam under otherwise identical conditions. Preferably, but not necessarily, the functionalized metallic surface is characterized by a hemispherical emissivity of at least 0.85 over a wavelength range selected from the range of 0.2 μm to 20 μm and at a temperature selected from the range of about −125° C. to about 2,700° C. Preferably, but not necessarily, the functionalized metallic surface is characterized by a hemispherical emissivity selected from the range of 0.85 to 0.98, optionally 0.85 to 0.95, optionally 0.90 to 0.98, optionally 0.90 to 0.95, over a wavelength range selected from the range of 1 μm to 20 μm and at a temperature selected from the range of −128° C. to 2,624° C. Preferably, but not necessarily, the functionalized metallic surface is characterized by a hemispherical emissivity selected from the range of 0.85 to 0.98, optionally 0.85 to 0.95, optionally 0.90 to 0.98, optionally 0.90 to 0.95, over a wavelength range selected from the range of 7.5 μm to 14 μm and at a temperature selected from the range of −66° C. to 110° C.

In an embodiment, a density range is from between 1 and 40,000 structures per square mm.

Optionally, the functionalized metallic surface is characterized by broadband omni-directional hemispherical emissivity.

Optionally, the metal material comprises aluminum, iron, silver, titanium, copper, or a combination of these.

Optionally, pulsed laser beam is a femtosecond laser beam and the step of applying is a step of applying a femtosecond laser surface processing (FLSP) with the controlled fluence to the region of the metallic surface. Optionally, the applying FLSP with a controlled fluence includes applying a series of laser pulses having a fluence of between 0.3±20% J/cm² to 5.0±20% J/cm². Optionally, the fluence is between 2.5±20% J/cm² to 3.0±20% J/cm². Optionally, each of the pulses has a same wavelength of between 100±20% nm and about 21,000±20% nm. Optionally, each of the pulses has a same peak wavelength (i.e., wavelength at peak light intensity) of between 100±20% nm and about 21,000±20% nm. Optionally, each of the pulses has a same wavelength of 800±20% nm. Optionally, each of the pulses has a same peak wavelength of 800±20% nm.

Optionally, the environment containing oxygen comprises air.

In optional aspects, the step of applying comprises a first applying step and a second applying step; wherein the first applying step comprises applying a first pulsed laser beam with a first controlled fluence to the region of the metallic surface in an environment free of oxygen; wherein a plurality of microfeatures are formed in the metallic surface in the region during the step of first applying; wherein the second applying step comprises applying a second pulsed laser beam with a second controlled fluence to the region of the metallic surface in an environment comprising oxygen; and wherein the metal material in the region of the metallic surface ablates due to the applied second pulsed laser beam and wherein at least a portion of the ablated metal material oxidizes and redeposits on the plurality of microfeatures to produce one or more oxidized-metal-coated structures.

Aspects disclosed herein include a method for laser-processing a metallic surface to produce a functionalized metallic surface, the method comprising: providing a substrate having the metallic surface; a step of first applying a first pulsed laser beam with a first controlled fluence to the region of the metallic surface in an environment free of oxygen; wherein a plurality of microfeatures are formed in the metallic surface in the region during the step of first applying; and a step of second applying comprising applying a second pulsed laser beam with a second controlled fluence to the region of the metallic surface in an environment comprising oxygen; and wherein the metal material in the region of the metallic surface ablates due to the applied second pulsed laser beam and wherein at least a portion of the ablated metal material oxidizes and redeposits on the plurality of microfeatures to produce one or more oxidized-metal-coated structures. Optionally, the second controlled fluence is less than the first controlled fluence.

Aspects disclosed herein include a functionalized metallic surface that exhibits substantially broadband omni-directional hemispherical emissivity, the metallic surface comprising multiple oxidized-metal-coated structures produced by femtosecond laser surface processing (FLSP) with a controlled fluence. The oxidized-metal-coated structures are optionally microfeatures comprising a metal oxide layer. Optionally, the metal oxide layer is the topmost layer of the oxidized-metal-coated structures. Optionally, each of the one or more oxidized-metal-coated structures has an oxide metal layer having a thickness of between 0.1±20% μm to 100±20% μm or greater. Optionally, the thickness of the oxide metal layer, of each oxidized-metal-coated structure, is selected from the range of 1 μm to 100 μm, optionally 1 μm to 50 μm, optionally 5 μm to 50 μm, optionally 1 μm to 30 μm, optionally 5 μm to 30 μm, optionally 10 μm to 20 μm, optionally 15±20% μm. Optionally, each of the one or more oxidized-metal-coated structures has height of between 5.0±20% μm to 1,000±20% μm and/or a structural diameter of between 5.0±20% μm to 1,000±20% μm. Optionally, each of the one or more oxidized-metal-coated structures has peak-to-valley height selected from the range of 5.0 μm to 1,000 μm, optionally 5 μm to 500 μm, optionally 5 μm to 200 μm, optionally 50 μm to 200 μm, optionally 100 μm to 500 μm, optionally 100 μm to 400 μm, optionally 200 μm to 400 μm, optionally 100 μm to 1000 μm, optionally 200 μm to 1000 μm. Optionally, each of the one or more oxidized-metal-coated structures has a structural diameter selected from the range to 5.0 μm to 1,000 μm, optionally 5 μm to 500 μm, optionally 100 μm to 500 μm, optionally 100 μm to 400 μm, optionally 200 μm to 400 μm, optionally 100 μm to 1000 μm, optionally 200 μm to 1000 μm. The structural diameter is optionally equal to a full-width-at-half-maximum (FWHM) of a curve or function that approximates the shape of the structure or microfeature. The structural diameter is optionally a diameter of the structure or microfeature at a base of the structure or microfeature. Optionally, each of the one or more oxidized-metal-coated structures is a microfeature having a mound, pyramid, peak, or pillar cross-sectional outline. Optionally, the functionalized metallic surface has a 15% to 1200%, optionally 25% to 1200%, optionally 50% to 1200%, optionally 75% to 1200%, optionally 100% to at least 1200%, optionally 15% to at least 1500%, higher hemispherical emissivity than a planar metallic surface free of the oxidized-metal-coated structures under otherwise identical conditions. Preferably, but not necessarily, the functionalized metallic surface is characterized by a hemispherical emissivity of at least 0.85 over a wavelength range selected from the range of 0.2 μm to 20 μm and at a temperature selected from the range of about −125° C. to about 2,700° C. Preferably, but not necessarily, the functionalized metallic surface is characterized by a hemispherical emissivity selected from the range of 0.85 to 0.98, optionally 0.85 to 0.95, optionally 0.90 to 0.98, optionally 0.90 to 0.95, over a wavelength range selected from the range of 1 μm to 20 μm and at a temperature selected from the range of −128° C. to 2,624° C. Preferably, but not necessarily, the functionalized metallic surface is characterized by a hemispherical emissivity selected from the range of 0.85 to 0.98, optionally 0.85 to 0.95, optionally 0.90 to 0.98, optionally 0.90 to 0.95, over a wavelength range selected from the range of 7.5 μm to 14 μm and at a temperature selected from the range of −66° C. to 110° C.

Aspects disclosed herein include a method of producing a functionalized metallic surface that exhibits substantially broadband omni-directional hemispherical emissivity is provided. The method includes providing a substrate having a metallic surface, applying femtosecond laser surface processing (FLSP) with a controlled fluence to a region of the metallic surface in an environment containing oxygen, wherein metal material in the region of the metallic surface ablates due to the applied FLSP and wherein at least a portion of the ablated metal material oxidizes and redeposits on the metallic surface to produce one or more oxidized-metal-coated structures. Optionally, the metal material comprises aluminum, stainless steel, titanium, copper or gold.

In certain aspects, the step of applying FLSP with a controlled fluence includes applying a series of laser pulses having a fluence of between about 0.1 J/cm² to about 10.0 J/cm² or greater, for example, between about 0.3 J/cm² to about 5.0 J/cm², or between about 2.5 J/cm² to about 5.0 J/cm². In certain aspects, a reasonable wavelength range may be between about 100 nm to about 21,000 nm. In general, it is understood that FLSP is fairly wavelength independent and may be more dependent on the time scale of the pulse. In certain aspects, other parameters could be changed to change the fluence needed (e.g., processing at a different wavelength, repetition rate or pulse length; processing use multiple pulses with lower individual energy but similar total energy; process in different atmospheres; processing with the sample at different temperatures, etc).

In certain aspects, the environment containing oxygen includes nitrogen, air or other atmosphere. For example, there may be advantages to processing in other atmospheres such as limiting the oxide layer for applications that surface charging is an issue.

According to an embodiment, a functionalized metallic surface is provided that exhibits substantially broadband omni-directional hemispherical emissivity, the metallic surface comprising multiple oxidized-metal-coated structures produced by femtosecond laser surface processing (FLSP) with a controlled fluence. In certain aspects, each of the one or more oxidized-metal-coated structures has an oxide metal layer having a thickness of between about 0.1 μm to about 100 μm or greater. In certain aspects, each of the one or more oxidized-metal-coated structures has a height of between about 5.0 μm to about 1,000 μm and/or a structural diameter of between about 5.0 μm to about 1,000 μm.

Optionally, any method disclosed herein comprises scanning (e.g., rastering) the pulsed laser beam on the multi-layer during the step of irradiating thereby exposing the plurality of locations to the pulsed laser beam. Optionally, scanning (or, rastering) the pulsed laser beam may be accomplished or performed by (1) translating the laser beam and/or adjusting an angle of the laser beam at the layer or surface being irradiated, such as by using one or more mirrors to direct the laser beam, and/or by (2) changing a location of the irradiated the layer or surface relative to a location of the laser beam, such as using a movable/translatable and/or tiltable sample stage. Optionally, in any method disclosed herein, the step of scanning is characterized by a scan speed selected from the range of 0.01 mm/s to 10 m/s, optionally any value or range therebetween inclusively. Optionally, in any method disclosed herein, the pulsed laser beam is characterized by a pulse frequency selected from the range of 1 Hz to 100 MHz, optionally any value or range therebetween inclusively. Optionally, in any method disclosed herein, the pulsed laser beam is characterized by a pulse energy selected from the range of 1 nJ to 30 J, optionally any value or range therebetween inclusively. Optionally, in any method disclosed herein, the pulsed laser beam is characterized by a fluence selected from the range of 0.01 J/cm² to 100 J/cm², optionally any value or range therebetween inclusively. Optionally, in any method disclosed herein, the step of irradiating is characterized by a pulse length selected from the range of 1 fs to 10 ps, optionally selected from the range of 10 ps to 100 ns, optionally selected from the range of 1 fs to 100 ns, or optionally any value or range therebetween inclusively. Optionally, in any method disclosed herein, the step of irradiating is characterized by a spot density selected from the range of 10 to 50,000 spots/mm², optionally 10 to 50,000 spots/cm², optionally any value or range therebetween inclusively, optionally 10 to 50,000 spots/dm², optionally 10 to 50,000 spots/m², optionally 10 to 50,000 spots/m². Optionally, in any method disclosed herein, the step of irradiating is characterized by a spot density selected from the range of 10 to 5,000,000 spots/cm², optionally any value or range therebetween inclusively, such as optionally 10 to 500,000 spots/cm², optionally 100 to 500,000 spots/cm², optionally 1000 to 500,000 spots/cm², optionally 1000 to 300,000 spots/cm², optionally 10,000 to 500,000 spots/cm². Optionally, in any method disclosed herein, the pulsed laser beam is characterized by an average spot size selected from the range of 100 nm to 1 cm, optionally any value or range therebetween inclusively, such as optionally 1 μm to 1000 μm or optionally 1 μm to 1 cm. In some embodiments, parameters of the step of irradiating and of the pulsed beam laser may be controlled independently, including but not limited to, scan speed, pulse energy, fluence, spot size, pulse length, pulse density or pulses-per-area, and pulse frequency, to tune parameters of the microfeatures, including, but not limited to, thickness of one or more microfeature layers, microstructure of one or more microfeature layers, presence or absence and microstructure of the redeposited surface layer, peak-to-valley height, and presence or absence or thickness of an interfacial layer. In some embodiments, some parameters of the pulsed laser beam may be interdependent, such as scan velocity and repletion rate of the pulsed laser beam or pulse energy and beam diameter or spot size. Optionally, in any method disclosed herein, formation of the plurality of microfeatures during the step of irradiating comprises ablation (e.g., “valley ablation”) of portions of the starting multi-layer material that surround each microfeature.

Optionally, in any method, microfeature(s), composition, material, and system disclosed herein, each microfeature has a peak-to-valley height selected from the range of 1 μm to 500 μm, optionally any value or range therebetween inclusively. Optionally, in any method, microfeature(s), composition, material, and system disclosed herein, the microfeatures are arranged as an array on a substrate, the substrate comprising the first composition. Optionally, the array is periodic or semi-periodic. Optionally for any microfeature, each microfeature layer or each microfeature layer other than the surface redeposited-layer, if present, is in the form of a polycrystalline film. Optionally for any microfeature, each microfeature layer other than the surface redeposited-layer, if present, has a thickness selected from the range of 10 nm to 500 μm, optionally any thickness therebetween inclusively, optionally selected from the range of 1 μm to 500 μm. Optionally for any microfeature, each microfeature is a mound or pillar. Optionally for any microfeature, each microfeature has a peak-to-valley height selected from the range of 1 μm to 500 μm, optionally any thickness therebetween inclusively. Optionally for any microfeature, an interface between any two microfeature layers is compositionally abrupt or comprises an interfacial layer; wherein the interfacial layer has thickness less than 10 μm and has an interfacial composition comprising a mixture of a composition of each of the microfeature layers adjacent to the interfacial layer.

Without wishing to be bound by any particular theory, there may be discussion herein of beliefs or understandings of underlying principles relating to the devices and methods disclosed herein. It is recognized that regardless of the ultimate correctness of any mechanistic explanation or hypothesis, an embodiment of the invention can nonetheless be operative and useful.

### BRIEF DESCRIPTION OF THE DRAWINGS

FIGS. 1A-1C: Near perfect broadband omnidirectional emissivity response.

FIG. 1A: Directional emissivity as a function of emission angle. Zero degrees corresponds with the detector normal to the surface. The average hemispherical emissivity (Eₕ) value is also shown. FIG. 1B: 3D LSCM topographic map of the aluminum laser-processed surface, according to embodiments herein, having the oxidized-metal-coated structures, according to embodiments herein, with an inset SEM image of a single mound. FIG. 1C: The spectral directional emissivity of the same surface showing that near perfect broadband omnidirectional emissivity response is obtained. Emissivity values were measured every 10 degrees (from 10 to 80) and approximately every 0.1 μm and smoothed using interpolation.

FIGS. 2A-2I: Surface and subsurface images, and emissivity of samples produced in nitrogen environment. FIGS. 2A-2C: SEM images of samples produced at the fluence specified in the grey box in the top middle of each image for a constant pulse count of 1865. FIGS. 2D-2F: SEM images of FIB cross-sectioned mounds to show subsurface structure of the corresponding sample in FIGS. 2A-2C. The term “PPL” stands for “protective platinum layer” that is deposited during the cross-sectioning process. FIGS. 2G-2I: The corresponding directional and hemispherical emissivity of each sample in the same column (i.e., FIGS. 2A, D, and G correspond to the same sample; similarly FIGS. 2B, E, and H all correspond to the same sample; and FIGS. 2C, F and I correspond to the same sample). The represented in FIGS. 2A-2I are free of an oxide layer due to having been formed in absence of oxygen.

FIGS. 3A-3I: Surface and subsurface images, and emissivity of samples produced in air, an exemplary oxygen-containing environment. FIGS. 3A-3C: SEM images of samples produced at the fluence specified in the grey box in the top middle of each image for a constant pulse count of 1865. The images show metallic surfaces having oxidized-metal-coated structures produced according to embodiments of methods disclosed herein. FIGS. 3D-3F: Ion beam images of FIB Cross-Sectioned mounds to show subsurface structure of the corresponding sample in FIGS. 3A-3C. PPL stands for protective platinum layer that is deposited during the cross-sectioning process. FIGS. 3G-3I: The corresponding directional and hemispherical emissivity of each sample in the same column (i.e., FIGS. 3A, D, and G correspond to the same sample; similarly, FIGS. 3B, E, and H all correspond to the same samples; and FIGS. 3C, F and I correspond to the same sample). The represented in FIGS. 3A-3I comprise an oxide layer.

FIGS. 4A-4F: Cross-sectional images of three samples processed in open air at the same pulse count and fluence to compare the oxide layer thickness for different amounts of etching. The images show metallic surfaces having oxidized-metal-coated structures produced according to embodiments of methods disclosed herein. The cross section in FIGS. 4A-4B was performed directly after laser processing. The remaining samples were acid etched, in a 2% solution for 60 minutes (FIGS. 4C-4D), and a 10% solution for 60 minutes (FIGS. 4E-4F). The green boxes in the SEM images of FIGS. 4A, 4C and 4E illustrate the zoomed area for the pictures shown in FIGS. 4B, 4D and 4F, respectively. FIGS. 4B, 4D and 4F are images produced using the ion beam as the illumination source, which causes the oxide layer to appear black. The bright layer on top of the oxide is a thin protective platinum layer added during the cross-sectioning process.

FIGS. 5A-5E: Simulations of FLSP-processed metallic surfaces having oxidized-metal-coated structures produced according to embodiments of methods disclosed herein. FIG. 5A: Simulations of directional and hemispherical emissivity for hemispherical mounds of aluminum with no oxide layer on top. FIG. 5C: Simulations of directional and hemispherical emissivity for hemispherical mounds of aluminum with an oxide layer on top. FIG. 5D: 3D schematic representing a periodic arrangement of the supercell used to calculate the results in FIG. 5C. FIGS. 5B and 5E: Dimensions of the supercell used in the simulations for the emissivity results shown in FIGS. 5A and 5C, respectively. The presented simulations accurately agree with the obtained experimental results.

FIG. 6: Depiction of emissivity measurement setup. In our case, the origin represents the sample and the sensor is the thermal imaging camera. Samples were tested to verify no dependence of emissivity on the reference angle.

FIG. 7: Measured and calculated values for hemispherical emissivity of bare flat aluminum. Left: Computed directional emissivity of bare aluminum measured using the thermal camera method as compared to theoretical and simulated values. The calculated and simulated data do not take into account the surface roughness of the bare aluminum. Right: The hemispherical emissivity calculations compared to the theoretical and simulated values. The theoretical value was calculated using the equations in Siegel, Robert Howell, J. R. Thermal Radiation Heat Transfer. (Taylor and Francis Group, 1992).

FIGS. 8A-8C: Directional and hemispherical emissivity measurements of exemplary metallic surfaces having oxidized-metal-coated structures, produced according to embodiments of methods disclosed herein. Measurements made using the (FIG. 8A) reflection method, (FIG. 8B) TIC method, and (FIG. 8C) simulations. Hemispherical emissivity is the integral over all angles and directions for a specific wavelength range, and total hemispherical emissivity is the integral of the hemispherical emissivity over all wavelengths. For these figures, Eₕ is the hemispherical emissivity integrated over the wavelength range of 7.5-14 microns; Eₕ is defined the same for all figures herein.

FIGS. 9A-9L: SEM images, as well as directional and hemispherical emissivity of surfaces processed in nitrogen. FIGS. 9A-9F: SEM images of samples having metallic surfaces having structures, produced according to embodiments of methods disclosed herein except in absence of oxygen, using different fluences for a constant pulse count of 1865. FIGS. 9G-9L: The directional and hemispherical emissivity of the samples. The SEM image in FIG. 9A corresponds to the emissivity plot in FIG. 9G, FIG. 9B corresponds to FIG. 9H, and so on.

FIGS. 10A-10L: SEM images, as well as directional and hemispherical emissivity of surfaces processed in Air. FIGS. 10A-10F: SEM images of samples having metallic surfaces having oxidized-metal-coated structures, produced according to embodiments of methods disclosed herein, in an oxygen-containing environment (air), using different fluences for a constant pulse count of 1865. FIGS. 10G-10L: The directional and hemispherical emissivity of the samples. The SEM image in FIG. 10A corresponds to the emissivity in FIG. 10G, FIG. 10B corresponds to FIG. 10H, and so on.

FIGS. 11A-11B: Surface and subsurface images for a sample having metallic surfaces having oxidized-metal-coated structures, produced according to embodiments of methods disclosed herein, produced in an air environment to show the decrease in thickness of the oxide layer moving down into the pit. FIG. 11A: Surface SEM image of a sample produced at the fluence specified in the grey box in the top middle of the image for a constant pulse count of 1865. FIG. 11B: Ion beam image of the area through a pit between two mounds (line shown in middle of FIG. 11A) that was cross sectioned with the FIB mill to show the subsurface structure.

FIGS. 12A-12D: Theoretical simulations of hemispherical and directional emissivity for a flat thick aluminum film with varying thickness of top oxide. FIG. 12A: The schematic of the system used in the simulations. Simulation results for an oxide layer thicknesses of (FIG. 12B) 5 μm, (FIG. 12C) 15 μm, and (FIG. 12D) 20 μm.

FIGS. 13A-13B: Hemispherical emissivity as a function of (FIG. 13A) average roughness and (FIG. 13B) average height in both open air and nitrogen environments.

FIG. 14: An illustration of depicting a metallic surface having exemplary oxidized-metal-coated structures, according to some embodiments herein, which yield perfect hemispherical emissivity.

FIGS. 15A-15D: Near perfect broadband omnidirectional emissive response of FLSP on stainless steel. FIG. 15A: Emissivity as a function of angle from normal to surface for best performing results on stainless steel. FIG. 15B: 3D topographic map of the laser processed surface having metallic surfaces having oxidized-metal-coated structures, produced according to embodiments of methods disclosed herein. Insert: SEM images of a single microstructure mound. FIG. 15C: Surface SEM image of the same sample. FIG. 15D: SEM image of FIB mill cross-sectioned pyramid to show subsurface structure. The cross-section was complete along the line shown in middle of FIG. 15C. PPL stands for protective platinum layer that is deposited before the cross-sectioning.

FIGS. 16A-16F: SEM images and emissivity for FLSP applied to different materials. FIGS. 16A-16C: SEM images of the surfaces having metallic surfaces having oxidized-metal-coated structures, produced according to embodiments of methods disclosed herein, from left to right: 99% pure silver, grade 5 titanium, and copper 101.

FIGS. 16D-16F: Directional and hemispherical emissivity of FLSP applied to, from left to right: 99% pure silver, grade 5 titanium, and copper 101, for the corresponding surface in the SEM image above each plot.

### STATEMENTS REGARDING CHEMICAL COMPOUNDS AND NOMENCLATURE

In general, the terms and phrases used herein have their art-recognized meaning, which can be found by reference to standard texts, journal references and contexts known to those skilled in the art. The following definitions are provided to clarify their specific use in the context of the invention.

The term “functionalized” generally refers to a surface processed or modified, such as according to embodiments of methods disclosed herein, where the functionalization yields higher emissivity values compared to same or equivalent but pre- or un-functionalized metallic surface. More particularly, a functionalized metallic surface is one that comprises of microscale structures with oxidized-metal-coated outer layer, according to embodiments disclosed herein.

Various potentially useful aspects, embodiments, definitions, aspects, measurement techniques, mechanisms, theories, and/or background information may be found in the following publications, each of which is incorporated herein in its entirety, to the extent not inconsistent herewith: (1) E. Peng, et al. “Micro/nanostructures formation by femtosecond laser surface processing on amorphous and polycrystalline Ni₆₀Nb₄₀”, Applied Surface Science, Volume 396, 28 Feb. 2017, Pages 1170-1176; (2) E. Peng, et al., “Growth mechanisms of multiscale, mound-like surface structures on titanium by femtosecond laser processing,” Journal of Applied Physics 122, 133108 (2017); doi 10.1063/1.4990709; (3) E. Peng, et al., “Formation of Mound-Like Multiscale Surface Structures on Titanium by Femtosecond Laser Processing,” University of Nebraska-Lincoln Spring 2017 Research Fair, Graduate Student Poster Session, Apr. 5, 2017; (4) C. A. Zuhlke, et al. (“Superhydrophobic metallic surfaces functionalized via femtosecond laser surface processing for long term air film retention when submerged in liquid”, Proc. SPIE 9351, Laser-based Micro- and Nanoprocessing IX, 93510J (12 Mar. 2015), doi:10.1117/12.2079164); and (5) G. Beard, et al. (“Embedding Silver into Aluminum Surfaces Using Femtosecond Laser Surface Processing,” Nebraska Academy of Sciences Annual Meeting, virtual, Apr. 23, 2021). For example, some compositions of layers and microfeatures as well as process parameters, such as characteristics of the pulsed laser beam, described in the aforementioned publications may be useful optional embodiments herein, and are hereby incorporated as such.

In various embodiments, each oxidized-metal-coated structure disclosed herein is a microfeature having a metal oxide layer. Optionally, the metal oxide layer is a topmost layer of the microfeature. The term “microfeature” refers to a feature or object having at least one characteristic physical dimension that is selected from the range of 1 μm to 1000 μm. The at least one characteristic physical dimension of the microfeature may be, but is not limited to, a height, a width, a diameter, a full-width-at-half-maximum (FWHM) of a curve or function that approximates the shape of the feature, an amplitude (or, height) of a curve or function that approximates the shape of the feature, a peak-to-valley height, etc. The feature may be a microstructural feature or object, such as a mound or pillar. The feature is optionally, but no necessarily, rising from, tethered to, attached to, compositionally continuous with, connected to, and/or otherwise associated with a surface, such as a surface of a layer, film, or material. “Mounds” described and characterized throughout herein are exemplary microfeatures, according to embodiments herein. The microfeatures described herein are multi-layered and multi-material structures, which may also be referred to herein as self-organized structures and surface structures. The microfeatures may be hierarchical, comprising both microscale and nanoscale features. For example, a re-deposited surface layer, which often comprises a mixture of the composition of a plurality of the starting layers, may have nanoscale features such as nanoparticles, in addition to microparticles. The combination of micro- and nano-scale features may provide enhanced properties of these surfaces, such as hydrophilicity.

The term “peak-to-valley height” refers to a characteristic physical dimension of a microfeature corresponding to a height of the microfeature between its peak and the lowest point nearby or adjacent to the microfeature, such as the lowest point of a region that may be described as a valley nearest to the microfeature. The microfeature's peak generally refers to the topmost point of the microfeature, a point farthest from a characteristic geometric plane or axis of a layer or surface from which the microfeature rises, or point farthest from or opposite of a base of the microfeature, or a point that corresponds to a peak of a curve or function that approximates the shape of the microfeature. Optionally, but not necessarily, the valley of the peak-to-valley measure may correspond to a lowest point or baseline of a curve or function that approximates the shape of the microfeature. Optionally, but not necessarily, the valley of the peak-to-valley measure may correspond to a lowest point between the microfeature being measure/characterized a nearest microfeature, or an average of the lowest points or positions between the microfeature being measure/characterized its nearest neighbor microfeatures. Measuring or determining the peak-to-valley height may include a laser scanning confocal microscope may be used to measure or determine the peak-to-valley height. The laser scanning confocal microscope creates a 3D surface topological map that can then be analyzed to get geometric data for the structures. Optionally, if a microfeature is titled with respect to its respective substrate layer, such as the first starting layer, (or, has a longitudinal axis not normal or perpendicular to a characteristic plane of its substrate layer) then either the peak-to-valley along the microfeature's tilted or longitudinal axis or along an axis perpendicular to its substrate layer may be used to measure the peak-to-valley height. Additional descriptions and information pertaining to determining the peak-to-valley height may be found in A. Tsubaki, et al. (“Multi-material, multi-layer femtosecond laser surface processing”, in Proc. SPIE Vol. 11674, Laser-based Micro- and Nanoprocessing XV, Mar. 10, 2021, doi 10.1117/12.2582756), which is incorporated herein by reference in its entirety.

The term “metal element” refers to a metal element of the periodic table of elements. Optionally, the term “metal element” includes elements that are metalloids. Metalloids elements include B, Si, Ge, As, Sb, and Te. Optionally, metalloid elements include B, Si, Ge, As, Sb, Te, Po, At, and Se. The term “metal” is intended to be consistent with the term as known in the field of materials science, and generally refers to a material having a composition comprising one or more metal elements and which when/if freshly prepared, polished, or fractured, in isolated form, shows a lustrous appearance, and conducts electricity and heat relatively well. As used herein, a metal may be metal alloy, such as, but not limited to, any steel, such any stainless steels. As would be recognized by one skilled in the art, including the field of material science, a metal alloy is a metal whose composition comprises two or more metal elements.

As would be recognized by one skilled in the relevant arts, particularly in the fields of laser technologies or laser ablation technologies, a “pulsed laser beam” refers to a laser beam of a pulsed laser, or laser beam having pulses of laser irradiation, any two pulses being separated by a period of zero or near-zero intensity of the laser light, characterized by a pulse frequency.

Generally, a layer refers a configuration, structure, or geometry that may be characterized or described generally by a characteristic geometric plane (or, two-dimensional geometric surface) or a two-dimensional surface and a thickness (or average thickness) of the characteristic geometric plane or the two-dimensional surface along an axis normal or perpendicular to said characteristic geometric plane or two-dimensional surface. A thin film, as the term would be known by one of skill in the field of materials science, is an example of a layer. Optionally, a layer may be conformal with a respective substrate surface or layer. Optionally, a layer may be non-conformal with a respective substrate surface or layer.

The term “spot size” is intended to be consistent with the term of art, particularly in the fields of optics, lasers, and laser processing of materials, and generally refers to a diameter of the laser beam at a point of first impinging upon or first intersecting with a material or object, such as a layer or a surface, or a portion thereof. A laser beam may be characterized by an average spot size.

The term “spot density” refers to a number of discrete locations irradiated by a pulsed laser beam per area of a material, surface, layer, or object being irradiated.

As used herein, the term “microstructure” is intended to have the same meaning as the same term in the art of material science, and generally refers to characteristics of a material (or, layer, film, or object thereof) including, but not limited to, average size of grains or crystallites, size distribution of grains or crystallites, orientation (e.g., random, textured, etc.) of grain or crystallites, and where the material is single crystalline, polycrystalline, or amorphous.

Additional nomenclature and technical descriptions are provided below and throughout.

The term “and/or” is used herein, in the description and in the claims, to refer to a single element alone or any combination of elements from the list in which the term and/or appears. In other words, a listing of two or more elements having the term “and/or” is intended to cover embodiments having any of the individual elements alone or having any combination of the listed elements. For example, the phrase “element A and/or element B” is intended to cover embodiments having element A alone, having element B alone, or having both elements A and B taken together. For example, the phrase “element A, element B, and/or element C” is intended to cover embodiments having element A alone, having element B alone, having element C alone, having elements A and B taken together, having elements A and C taken together, having elements B and C taken together, or having elements A, B, and C taken together.

The term “±” refers to an inclusive range of values, such that “X±Y,” wherein each of X and Y is independently a number, refers to an inclusive range of values selected from the range of X−Y to X+Y. In the cases of “X±Y” wherein Y is a percentage (e.g., 1.0±20%), the inclusive range of values is selected from the range of X-Z to X+Z, wherein Z is equal to X·(Y/100). For example, 1.0±20% refers to the inclusive range of values selected from the range of 0.8 to 1.2.

In an embodiment, a composition or compound of the invention, such as an alloy or precursor to an alloy, is isolated or substantially purified. In an embodiment, an isolated or purified compound is at least partially isolated or substantially purified as would be understood in the art. In an embodiment, a substantially purified composition, compound or formulation of the invention has a chemical purity of 95%, optionally for some applications 99%, optionally for some applications 99.9%, optionally for some applications 99.99%, and optionally for some applications 99.999% pure.

### DETAILED DESCRIPTION

In the following description, numerous specific details of the devices, device components and methods of the present invention are set forth in order to provide a thorough explanation of the precise nature of the invention. It will be apparent, however, to those of skill in the art that the invention can be practiced without these specific details.

Overview:

The present embodiments provide functionalized metallic surfaces with excellent to near perfect absorption/emission that is broadband and omnidirectional, and scalable processes for producing such processed metallic surfaces.

In certain embodiments, femtosecond laser surface processing (FLSP) is used to directly alter the properties of a surface. With FLSP, permanent multiscale structural surface features are produced that are typically characterized by microscale mounds, or pyramidal structures, covered by a layer of redeposited nanoparticles (see, e.g., Zuhlke, C. A., Anderson, T. P. & Alexander, D. R. Formation of multiscale surface structures on nickel via above surface growth and below surface growth mechanisms using femtosecond laser pulses. Opt. Express 21, 8460 (2013); Zuhlke, C. A., Anderson, T. P. & Alexander, D. R. Comparison of the structural and chemical composition of two unique micro/nanostructures produced by femtosecond laser interactions on nickel. Appl. Phys. Lett. 103, (2013); Tsubaki, A. T. et al. Formation of aggregated nanoparticle spheres through femtosecond laser surface processing. Appl. Surf. Sci. 419, 778-787 (2017)). The resulting micro and nanoscale roughness, along with modified surface chemistry and subsurface microstructure, accounts for the emissivity properties attributed to these surfaces. These features form through a combination of ablation, redeposition, melting, fluid flow and resolidification (see, e.g., Zuhlke, C. A. Control and understanding of the formation of micro/nanostructured metal surfaces using femtosecond laser pulses. ProQuest (2012)). The surface morphology and chemistry can be directly controlled by processing parameters such as fluence, the number of pulses applied, and the atmospheric environment present when processing the surface (see, e.g., Tsubaki, A. et al. Oxide layer reduction and formation of an aluminum nitride surface layer during femtosecond laser surface processing of aluminum in nitrogen-rich gases. Laser-based Micro-Nanoprocessing XIII 22 (2019) doi:10.1117/12.2508812). The versatility of FLSP for producing tailored surface properties results in a wide range of applications, including improved anti-bacterial response, modified wettability, enhanced heat transfer properties, and tunable electromagnetic response. The FLSP technique has many advantages over other surface functionalization techniques: it results in a fully functionalized surface in a single processing step; it involves the creation of hierarchical micro and nanoscale surface features composed of the original material, making the surface highly permanent; it involves modification of the original surface without the net addition of mass; and it results in a minimized heat affected zone, so the surface can be modified without altering the bulk properties of the material.

Additional useful descriptions of relevant pulsed laser systems and methods, as well as various potentially useful descriptions, background information, terminology (to the extent not inconsistent with the terms as defined herein), mechanisms, compositions, methods, definitions, and/or other embodiments may be found in U.S. Pat. No. 17,333,885 (Tsubaki, et al., filed May 28, 2021), which is incorporated herein in its entirety to the extent not inconsistent herewith.

In certain aspects, aluminum surfaces processed using FLSP within an air environment provide near perfect hemispherical emissivity in the spectral range from 7.5 to 14 μm. The developed FLSP surfaces outperform the emissivity response of all coatings and metamaterial structures presented in the literature. Experimental and theoretical insights are provided herein to show that both surface oxidation and multiscale surface features play important roles in the large emissivity increase. A detailed surface and subsurface analysis of chemistry, porosity, and microstructure enables the complete characterization of the FLSP surfaces and provides inputs to the performed theoretical modeling of light scattering from these surfaces. The laser processed surfaces produced according to embodiments herein are ideal candidates to be used as a permanent solution to achieve passive radiative cooling of large area metallic surfaces, thermophotovoltaics, thermal management in spacecrafts, and energy absorption for laser power beaming or stealth technologies.

In certain aspects, a system for laser processing a substrate sample includes a femtosecond laser system, beam delivery and focusing optics, motorized 3D stages, sample environmental chamber, and a computer to control the system. For a sample processed in different background gases, the surface processing may be completed in a vacuum chamber attached to the motorized stages with a desired flow rate, e.g., of 20-25 scfh, of the respective gas at atmospheric pressure. Laser input power may be adjusted to account for loss from the input window of this chamber. The femtosecond laser systems may include a titanium (Ti):sapphire based amplified systems (a Coherent Inc. Legend Elite Duo and a Coherent Inc. Astrella) generating 35 fs pulses, with a central wavelength of 800 nm, a pulse repetition rate of 1 kHz, and a maximum output pulse energy of 10 mJ and 6 mJ respectively. One skilled in the art will understand that other lasers are useful and that other laser parameters may be used as desired, e.g., wavelength, pulse size and rate, energy, etc.

Broadband and Omnidirectional Emissivity Response:

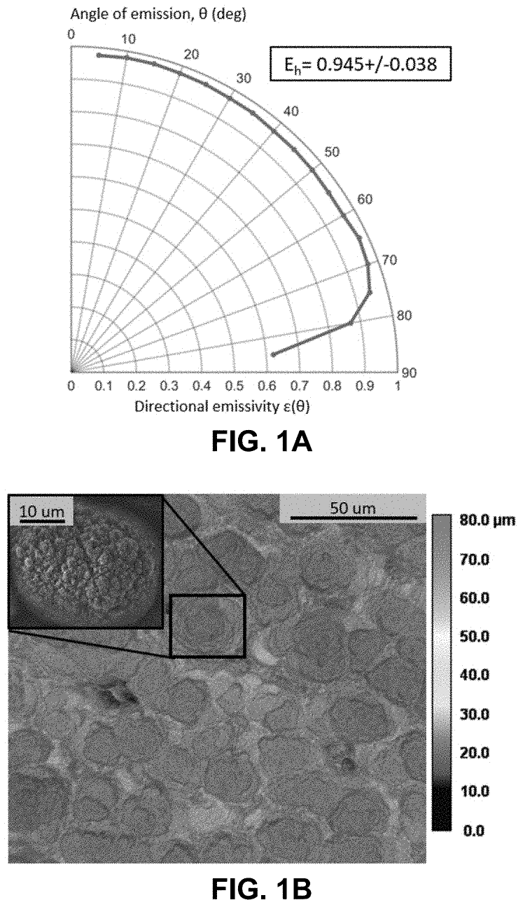

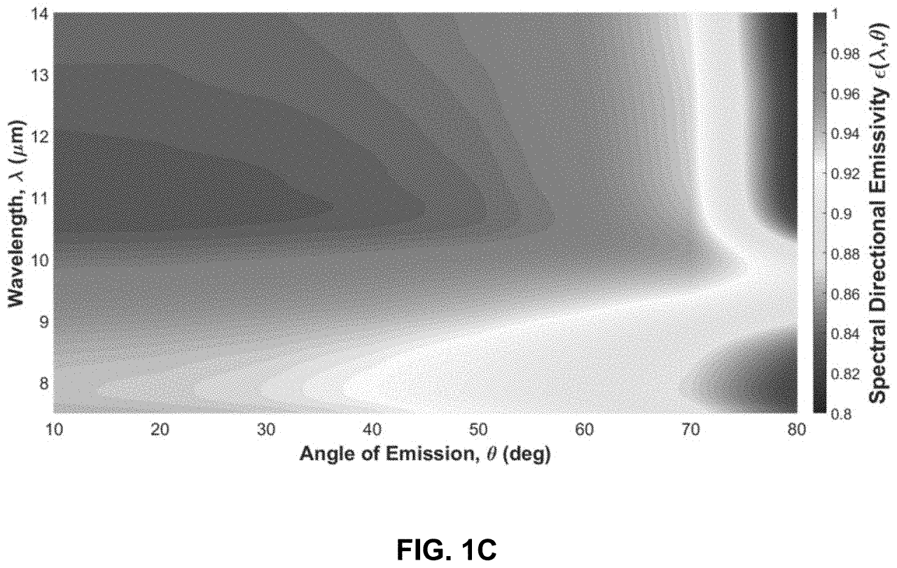

An omnidirectional increase in emissivity of aluminum that results in a hemispherical emissivity near the absolute maximum value of unity in the spectral range of 7.5 to 14 μm is demonstrated. It should be appreciated that this is just a range that the measurement equipment covered; the FLSP surfaces herein have high emissivity for a much broader spectral range. The directional emissivity of a typical optimized FLSP-processed metallic surface having the oxidized-metal-coated structures, according to certain embodiments herein, is illustrated in FIG. 1A and FIG. 1C. The surface topography is shown in the three dimensional (3D) laser scanning confocal microscope (LSCM) image and inset scanning electron microscope (SEM) image in FIG. 1B. This sample was processed in the air environment by using a 35 fs ultrafast laser with a fluence of 2.86 J/cm² and a pulse count of 1600 pulses. The microscale surface features typically may be characterized as mounds with heights in the range of 80 to 90 μm, for example. Significant variation in mound diameters are visible in the LSCM image in FIG. 1B. This variation in size is important to achieve the broadband high emissivity response. In order to show that FLSP is highly repeatable to produce near perfect thermal emitters, the optimized surface was reproduced with the same laser processing parameters using two different femtosecond laser systems at three different humidity levels with constant temperature in the lab, in a total of six batches. The hemispherical emissivity (Eₕ) value of 0.945 reported in FIG. 1A is the average Eₕ measurement of twelve samples, two per batch. More details about how the hemispherical and directional emissivities are calculated and their definitions are provided in the below sections. The standard deviation for the hemispherical emissivity of the twelve samples is also reported in FIG. 1 Error! Reference source not found. A. Due to the quasi-periodic self-organized nature of the resulting laser processed surface, the exact surface morphology at the microscale has some variation from one sample to another. However, the macroscale characteristics of the surfaces are uniform and repeatable for a given set of laser processing parameters. The emissivity remained high for a broad spectral range spanning an almost omnidirectional emission angle range, as shown in the measurements presented in FIG. 1C. Note that aluminum oxide has phonon-polariton resonances in the IR wavelength spectrum in the range of interest. The shift of the peak in emissivity from around 11 μm to around 10 μm with increased angle is likely due to a corresponding increase in the oxide thickness based on detection angle.

Effect of Surface Structure and Oxide on Emissivity:

Studies have demonstrated that the background or environmental gas, to which the metallic surface is exposed during FLSP processing, used during FLSP has a significant effect on the resulting surface features. For example, processing aluminum in a nitrogen environment has been shown to result in a significant increase in structure height and a reduction in the amount of oxide on the surface compared to structures produced in air (Tsubaki, A. et al. Oxide layer reduction and formation of an aluminum nitride surface layer during femtosecond laser surface processing of aluminum in nitrogen-rich gases. Laser-based Micro-Nanoprocessing XIII 22 (2019) doi:10.1117/12.2508812). Similarly, the background gas used during processing of silicon has been shown to have a significant effect on the structure shape and underlying chemistry. The oxide that builds up on the surface structures reported in this paper is likely in the form of oxidized nanoparticles that are created as a result of the laser ablation and deposited on the surface after each laser pulse; similar to the development of aggregated nanoparticle spheres that form using FLSP at low fluence values on aluminum (see, e.g., Tsubaki, A. T. et al. Formation of aggregated nanoparticle spheres through femtosecond laser surface processing. Appl. Surf. Sci. 419, 778-787 (2017); Zuhlke, C. A., Anderson, T. P. & Alexander, D. R. Fundamentals of layered nanoparticle covered pyramidal structures formed on nickel during femtosecond laser surface interactions. Appl. Surf. Sci. 283, 648-653 (2013)). In order to study the effect that the shape of the surface structure has on the emissivity, while maintaining a similar oxide layer thickness between samples, a series of samples were processed in a nitrogen environment with different laser fluences ranging from 0.58 to 4.05 J/cm². In addition, to study the role of the combination of surface structure and oxides, a series of samples were processed in an air environment for approximately the same range of laser fluences.

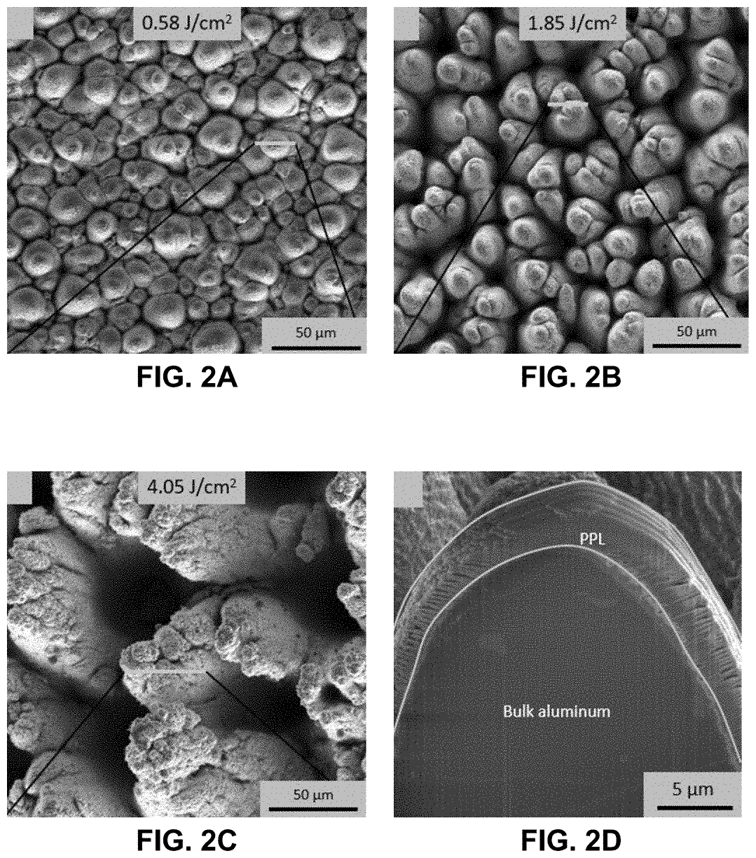

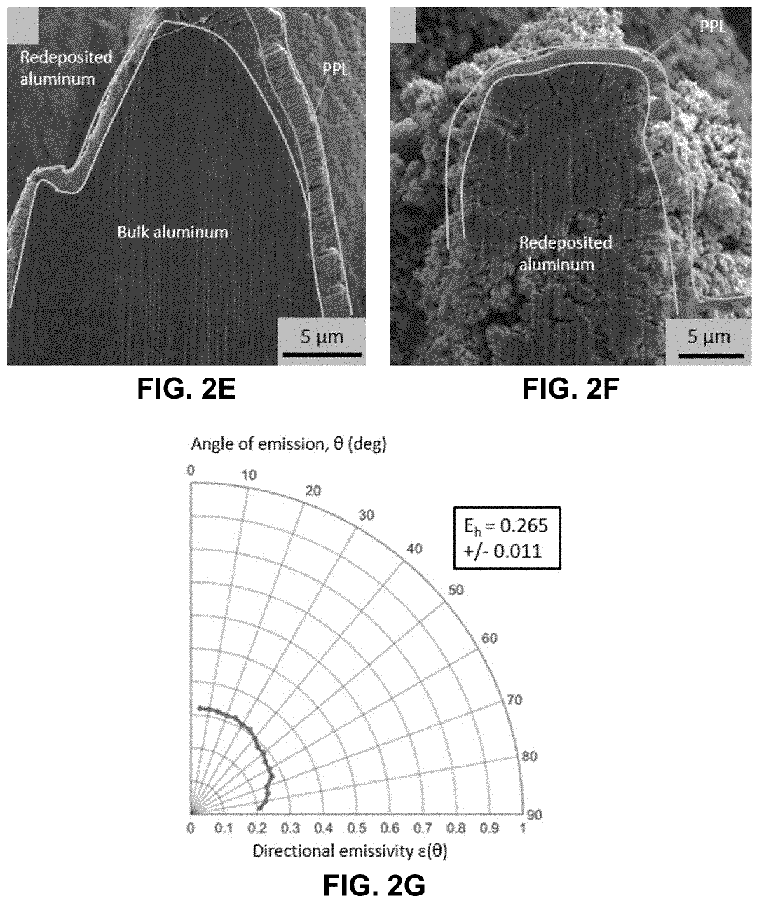

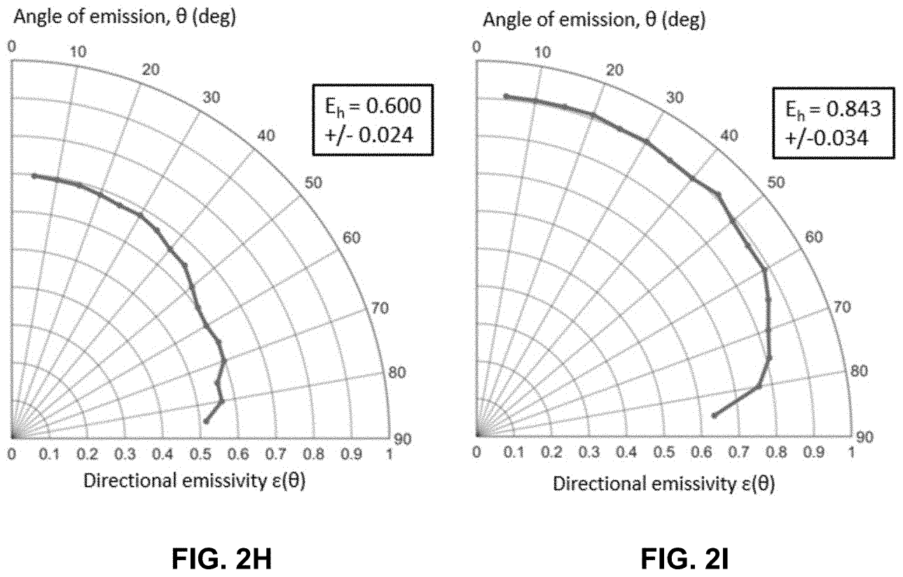

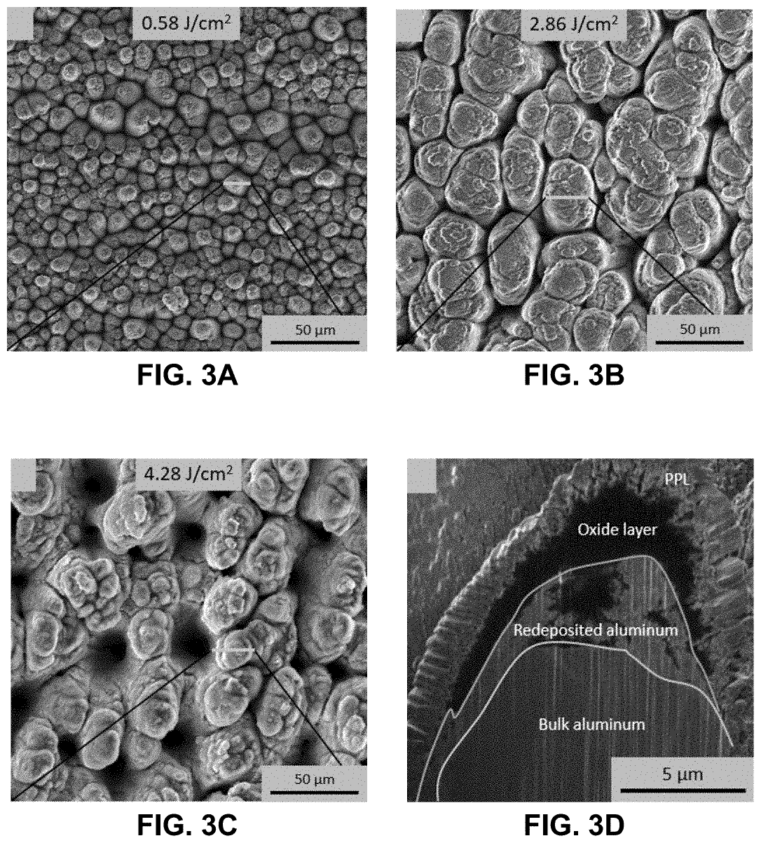

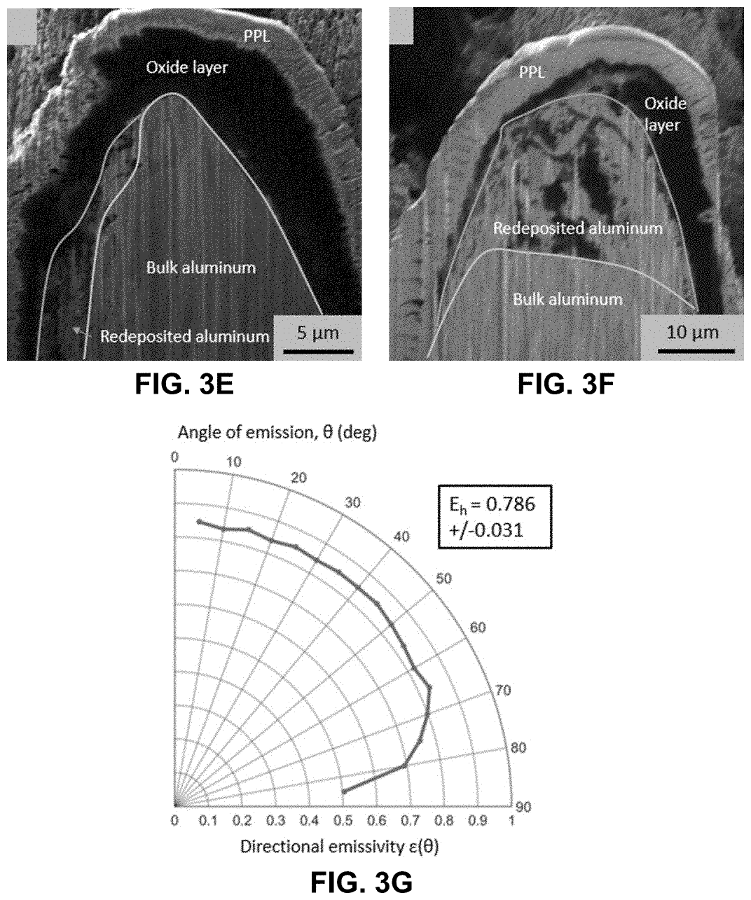

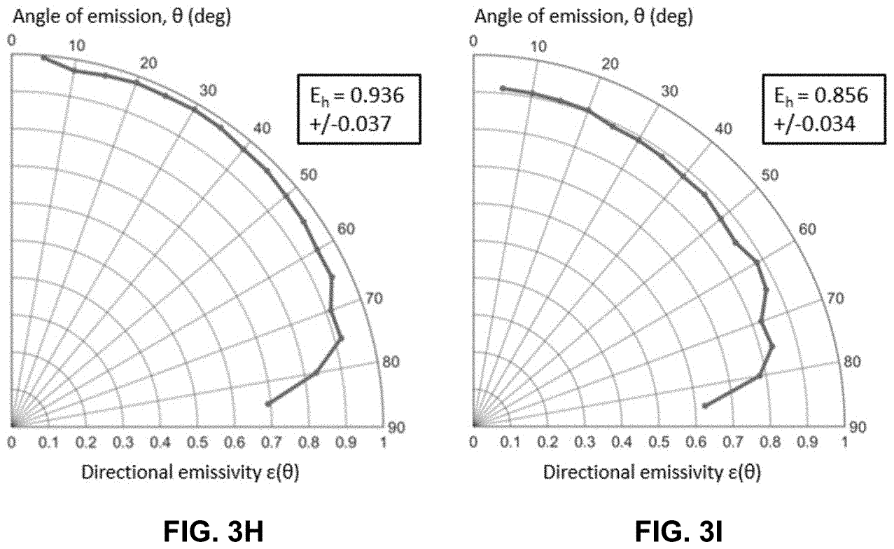

An LSCM was used to accurately measure the average structure height and surface roughness of each sample (see Table 1). The reported average height is given by the variable R_{z} measured at 10 different areas on the sample. In addition, a comparison between surface oxide layers was accomplished by using a dual-beam system with a scanning electron microscope (SEM) and a focused ion beam (FIB) mill to perform cross sections of the mounds for subsurface analysis of the structures. To prevent damage to the structures during the milling process, a protective ultrathin platinum layer (PPL) was deposited first. The cross-sectioned structures were analyzed using energy-dispersive X-ray spectroscopy (EDS) to accurately determine the average thickness of the oxide layer, which is reported in Table 1. Also included in Table 1 are the laser processing parameters, measured surface roughness parameters, and hemispherical emissivity results for each sample. SEM images of cross-sectioned structures for a variety of samples processed in a background gas of nitrogen or air are included in FIGS. 2A-2I and FIGS. 3A-3I, respectively. In some of the cross-sectional images, the divisions between layers are difficult to see; in these cases, contour lines have been used to better clarify the transitions. In FIGS. 2A-2I and FIGS. 3A-3I different techniques are utilized to image the cross-sectioned structures depending on the sample composition. Imaging with the ion beam highlights elemental contrast. For example, the oxide layer appears very dark as opposed to the aluminum. However, there is significant loss of resolution for imaging with the ion beam versus the electron beam. Use of the electron beam for imaging produces clearer images; however, non-conducting materials (like aluminum oxide) result in a charging effect that washes out the image. Therefore, for samples with a negligible oxide layer, such as those illustrated in Error! Reference source not found. D-2F, SEM images are presented. Whereas for samples with a thick oxide layer, like in FIG. 2 Error! Reference source not found. D-2F, ion beam images are presented instead. Additional SEM images and emissivity data for samples processed with different fluences can be found below.

TABLE 1
Laser processing parameters with corresponding surface roughness parameters and emissivity
for FLSP samples processed in either air or nitrogen.

| | | | | | | |
|---|---|---|---|---|---|---|
| Peak | | | Average | Average | Average | |
| Fluence | Pulse | | Oxide Layer | Roughness, | Height, Average | Hemispherical |
| (J/cm²) | Count | Figure | Thickness (μm) | Rₐ (μm) | R_{z} (μm) | Emissivity |

Nitrogen

| | | | | | | |
|---|---|---|---|---|---|---|
| 0.58 | 1865 | 2A | <0.5 | 6.03 +/− 0.1 | 57.26 +/− 0.3 | 0.265 +/− 0.011 |
| 1.14 | 1865 | — | — | 10.59 +/− 0.4 | 88.02 +/− 0.3 | 0.399 +/− 0.016 |
| 1.85 | 1865 | 2B | <0.5 | 18.33 +/− 0.6 | 127.69 +/− 3.5 | 0.600 +/− 0.024 |
| 2.29 | 1865 | — | — | 22.56 +/− 0.7 | 239.83 +/− 8.6 | 0.815 +/− 0.033 |
| 2.86 | 1865 | — | — | 35.59 +/− 1.1 | 317.56 +/− 14.3 | 0.852 +/− 0.034 |
| 3.43 | 1865 | — | — | 42.78 +/− 0.8 | 377.45 +/− 14.3 | 0.838 +/− 0.034 |
| 4.05 | 1865 | 2C | <0.5 | 52.86 +/− 1.9 | 496.67 +/− 38.5 | 0.843 +/− 0.034 |

Air

| | | | | | | |
|---|---|---|---|---|---|---|
| 0.58 | 1865 | 3A | 2.5 +/− 1.5 | 3.38 +/− 0.3 | 47.18 +/− 1.4 | 0.786 +/− 0.031 |
| 1.14 | 1865 | — | — | 9.97 +/− 0.8 | 94.01 +/− 3.8 | 0.865 +/− 0.035 |
| 2.23 | 1685 | — | — | 10.78 +/− 0.6 | 120.71 +/− 6.6 | 0.904 +/− 0.036 |
| 2.86 | 1865 | 3B | 6.5 +/− 2.5 | 12.44 +/− 0.5 | 130.43 +/− 2.3 | 0.937 +/− 0.038 |
| 3.43 | 1865 | — | — | 15.81 +/− 0.9 | 155.04 +/− 9.2 | 0.936 +/− 0.037 |
| 4.05 | 1865 | — | — | 22.92 +/− 0.7 | 179.40 +/− 5.2 | 0.926 +/− 0.037 |
| 4.28 | 1865 | 3C | 5.1 +/− 2.2 | 25.38 +/− 0.4 | 217.45 +/− 6.6 | 0.856 +/− 0.034 |

All samples processed in nitrogen have a negligible oxide layer thickness of less than 0.5 μm as reported in Table 1. The oxide layer is so thin on these samples that it is not visible in the SEM images in FIGS. 2D-2F. The oxide layer for all samples processed in nitrogen is significantly thinner than even the lowest fluence sample processed in air, which is shown in FIG. 3A and FIG. 3D. Because this oxide layer is consistently negligible for the samples processed in nitrogen, it is most likely a result of surface oxidation after the sample has been removed from the nitrogen environment. For the samples processed in nitrogen, as fluence is increased, the roughness and height increases. Furthermore, the thickness of the layer of redeposited aluminum increases with increased fluence. The layer of redeposited aluminum does not contain oxides. From the data in Table 1 as well as the images in FIGS. 2A-2I and FIGS. 3A-3I, it can be seen that the hemispherical emissivity increases with increased laser fluence. This also corresponds to an increase in roughness and structure height, until approximately 3 J/cm². Beyond 3 J/cm², the roughness and structure height continue to increase, however, there is no substantial change in emissivity which is found to even decrease at higher fluence values.

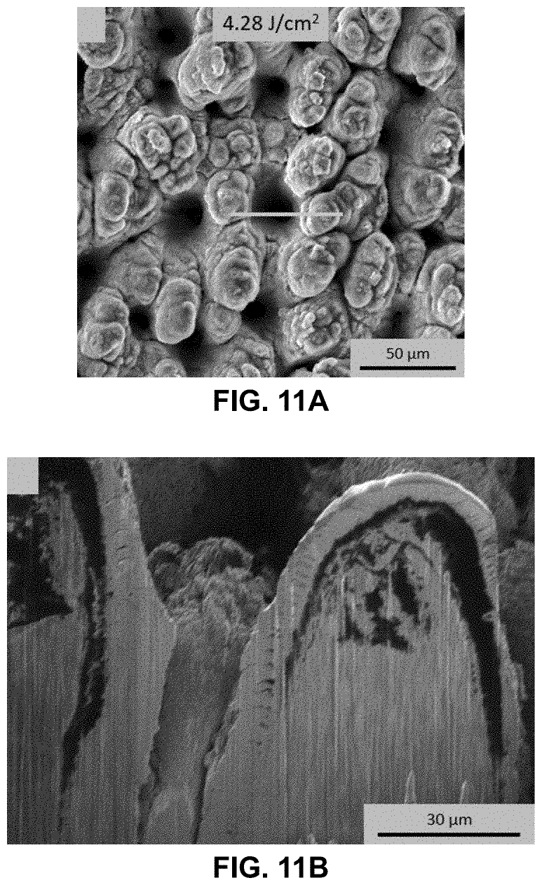

For samples produced in the air environment, there are similar trends to the ones produced in a nitrogen environment. First, for both processing environments, structure roughness, height, and the thickness of the redeposited layer increase with increased laser fluence as shown in Table 1 and FIGS. 3A-3I. However, one difference between the two processing environments can be seen in the redeposited layer. In the air environment, the aluminum nanoparticles that deposit onto the surface after ablation are oxidized and the thickness of the layer of oxidized nanoparticles increases with increased fluence. The importance of the oxidation is illustrated by the dramatically higher hemispherical emissivity values for the samples processed in air rather than nitrogen. For the low fluence values, there are no pits between the mound-like structures (see FIG. 3A) which causes a fairly uniform oxide layer across the surface. As the fluence is increased, the size of the pits between each structure increases (see FIG. 3B and FIG. 3C). The oxide layer is thinner in the pits than on the tops of the structures; therefore, the oxide layer is less uniform and thinner on average as the pit size increases, which yields a decrease in the emissivity. The oxide layer thickness on the top of the structures versus the transition into the pits is more clearly depicted in FIGS. 11A-11B, which illustrate a broader view of the cross section shown in FIG. 3C and FIG. 3F. This trend is further evidence that the oxide plays a significant role in the high emissivity value of the optimized FLSP surfaces. The crucial role that the oxide layer plays in the emissivity enhancement is also evident by making direct comparison between samples processed in air versus nitrogen. For example, the sample processed in nitrogen at a fluence of 2.86 J/cm² has an average surface roughness nearly three times greater than the sample produced in air, but the sample processed in air has a higher emissivity. A comparison between the two samples processed in air versus nitrogen at a fluence of 1.14 J/cm² shows that despite having similar roughness and height, the hemispherical emissivity of the sample processed in air is nearly double compared to the sample processed in nitrogen (see Table 1).

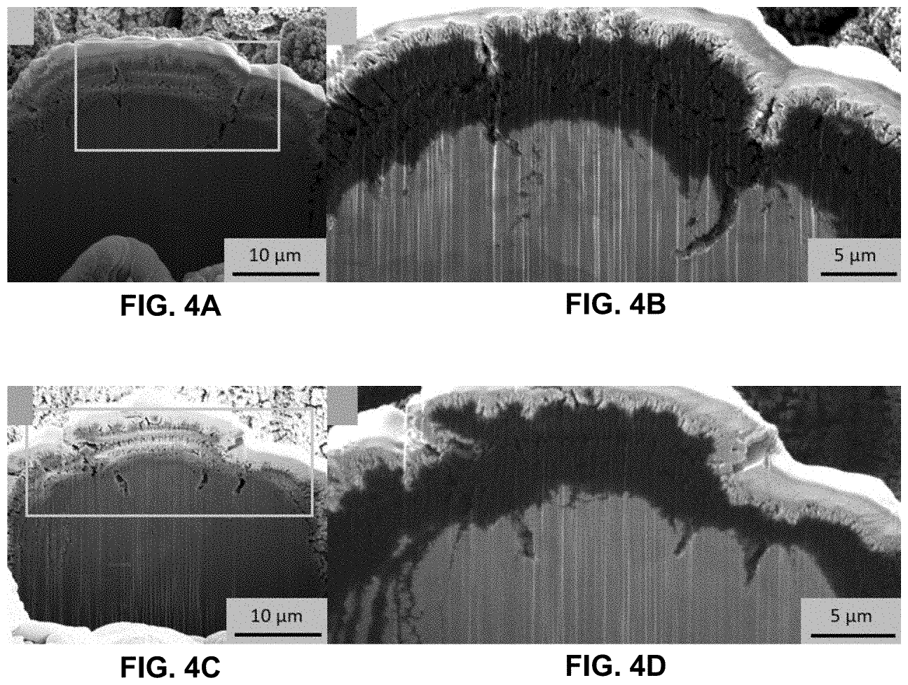

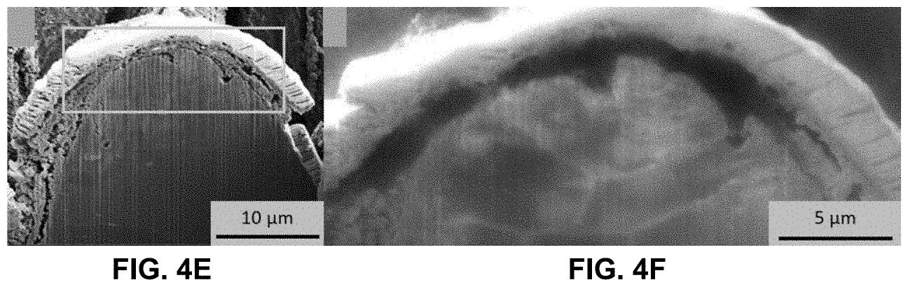

To examine the effect of the oxide layer, of the oxidized-metal-coated structures, according to certain embodiments herein, thickness on the emissivity more thoroughly, an acid etch technique was used to uniformly remove varying amounts of the surface oxide layer. The etching solution consisted of a mixture of chromic and phosphoric acids, which dissolves aluminum oxide with no significant effect on the underlying metal. The varied parameters for the etch duration and concentration are listed in Table 2, along with the average thickness of the oxide layer, measured surface roughness parameters, and hemispherical emissivity results. After etching the samples, mounds of similar size and shape were cross-sectioned. The results on the measured oxide layer thickness are included in Table 2 and FIGS. 4A-4F. The reported hemispherical emissivity values are the average of four measurements total across two samples for each etching amount, along with the standard deviation. After the acid etching, there is a consistent decrease in the hemispherical emissivity with a corresponding decrease in oxide layer thickness. In addition, there is a minor change in the structure height and average roughness after the acid etching, which is further evidence of the important role the oxide plays in the high emissivity values. There is a small drop in structure height with increased etching. This is likely because during FLSP there is preferential redeposition of the oxidized nanoparticle layer on the top of the mounds versus the valleys. Therefore, during etching more material is removed from the top of the structures than the valleys.

TABLE 2
Acid etching parameters with corresponding surface roughness
parameters and emissivity for FLSP samples all produced using the laser
parameters listed at the top of the table.
Processing Parameters: open air, fluence = 2.86 J/cm², pulse count = ~1600

| | | Average | | Average | |
|---|---|---|---|---|---|
| % Chromic acid | | Oxide Layer | Average | Height, | |
| in solution and | | Thickness | Roughness, Rₐ | Average | Hemispherical |
| etch time | Figure | (μm) | (μm) | R_{z} (μm) | Emissivity |
| no acid etch | 4A, B | 8.0 +/− 2.0 | 9.9 +/− 0.3 | 89.5 +/− 5.4 | 0.945 +/− 0.038 |
| 2% for 20 min | 4C, D | 6.0 +/− 1.2 | 11.1 +/− 0.2 | 82.8 +/− 4.7 | 0.864 +/− 0.035 |
| 2% for 60 min | — | 4.5 +/− 1.0 | 10.5 +/− 0.3 | 77.5 +/− 3.4 | 0.821 +/− 0.033 |
| 2% for 100 min | — | 2.0 +/− 0.9 | 10.5 +/− 0.2 | 77.5 +/− 3.3 | 0.795 +/− 0.032 |
| 10% for 60 min | 4E, F | 1.3 +/− 0.8 | 10.5 +/− 0.2 | 78.2 +/− 3.2 | 0.783 +/− 0.031 |
| 10% for 120 min | — | <1 | 9.0 +/− 0.6 | 65.9 +/− 2.3 | 0.657 +/− 0.026 |

Theoretical Modeling of the Laser-Processed Surfaces:

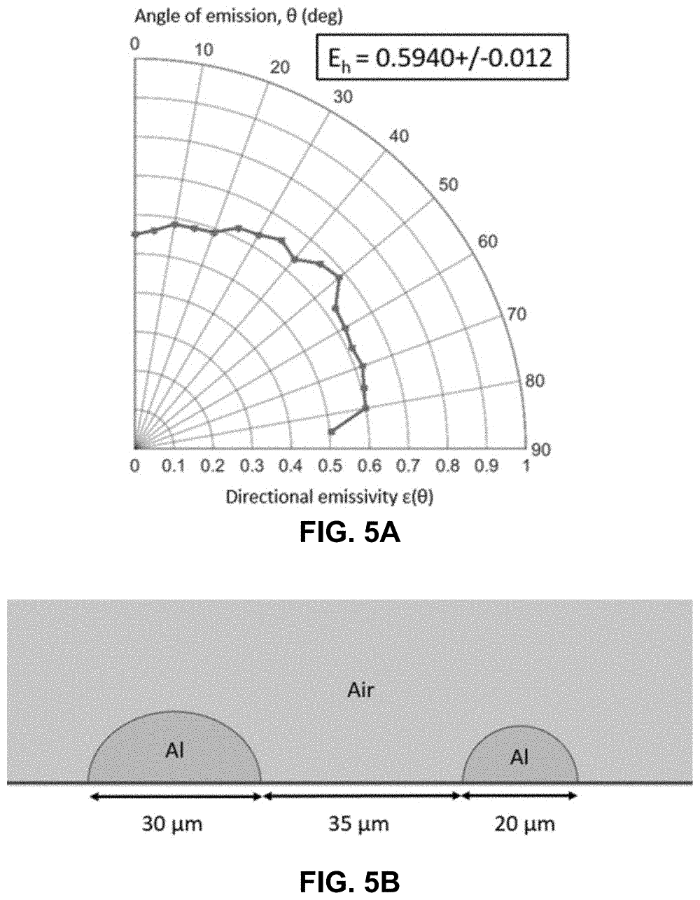

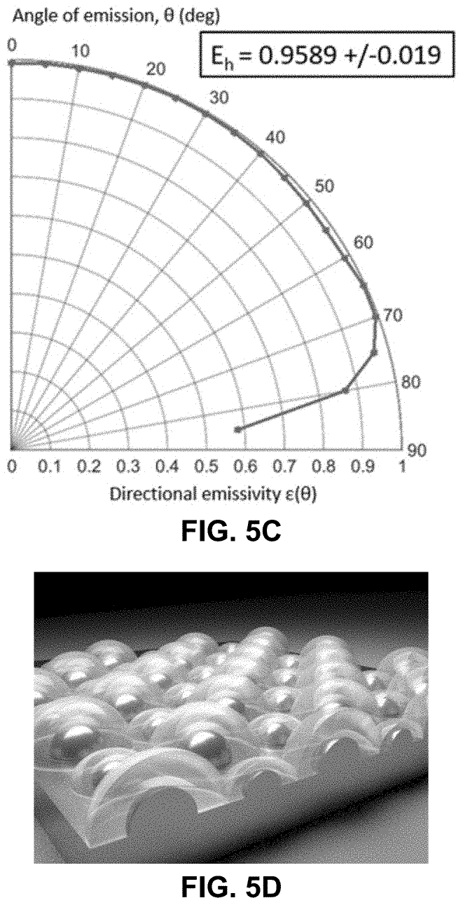

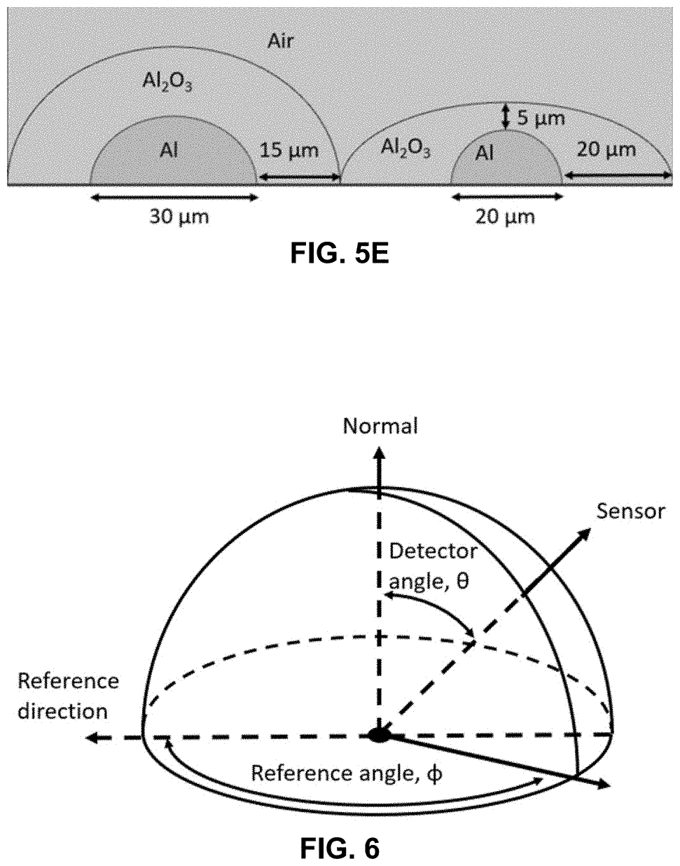

To theoretically demonstrate the effect that the oxide layer and surface morphology have on the emissivity, a full-wave electromagnetic simulations was performed utilizing the finite element method software, COMSOL Multiphysics. To this end, modelling and computing the thermal emission of a supercell composed of two hemispherical mounds with different dimensions and with varied oxide layer thickness were performed. The supercell mounds are surrounded by periodic boundary conditions at the left and right sides, as shown in FIG. 5B and FIG. 5E. The dispersive properties of aluminum and aluminum oxide are taken from experimental data. Note that aluminum oxide has phonon-polariton resonances at IR frequencies, leading to increased losses in this wavelength range and resulting in high emissivity. This resonance is centered around 11 μm and is demonstrated in FIG. 1C. As the angle of emission increases the resonance shifts toward shorter wavelengths because of the changing thickness in the oxide layer.

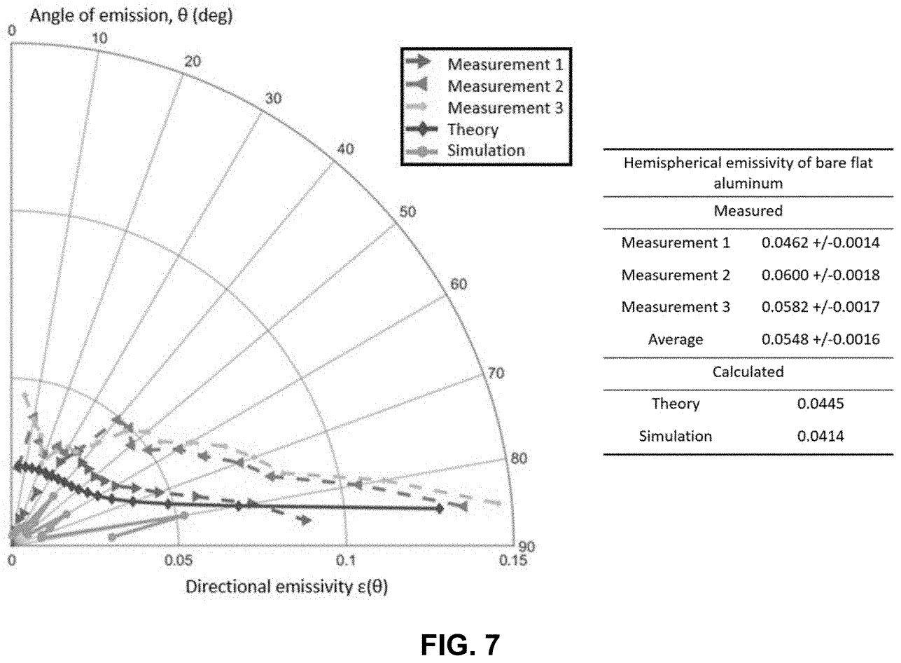

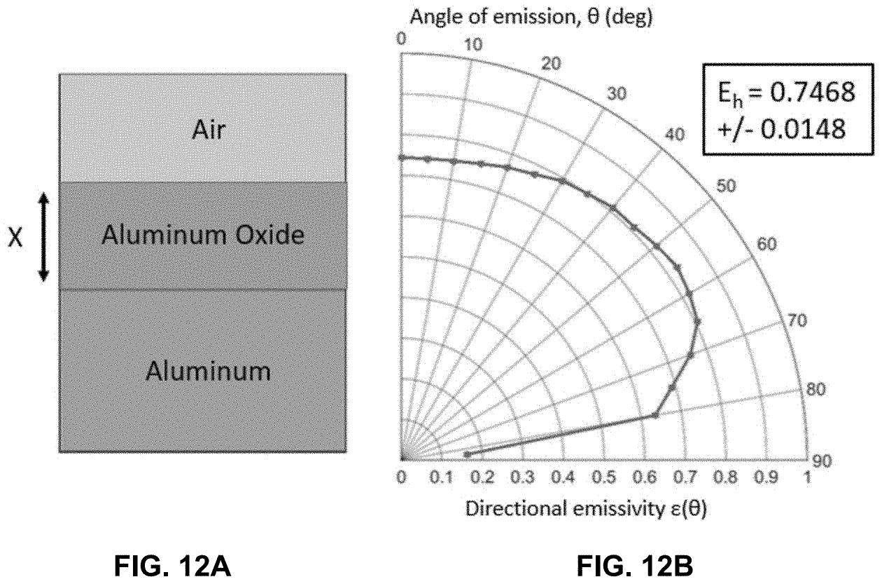

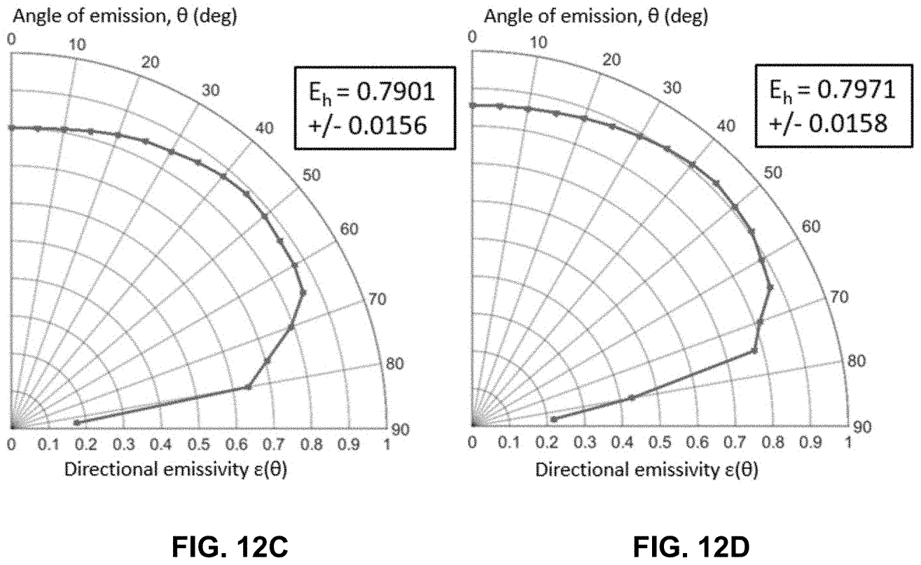

The dimensions of the supercell mounds are similar to the mounds shown in the cross sections in FIG. 4A. Note that the experimentally obtained FLSP surface features are not perfectly periodic, but the supercell used was found to be a good approximation to accurately model the presented structures without resorting to the extreme computational burden imposed by modeling random or quasi-periodic surface morphologies. The theoretical results are depicted in FIGS. 5A-5E. The theoretical simulation results are found to be in near perfect agreement with the experimental results. More specifically, both simulations predict an increase in emissivity over that of a bare flat aluminum surface, which has a hemispherical emissivity of 0.041, as shown in FIG. 7. There is also a substantial increase in emissivity for the FLSP surfaces over that predicted for a planar aluminum oxide layer on an aluminum substrate; these results are shown in FIGS. 12A-12D. The theoretical results of the bare (no oxide) aluminum mounds structure shown FIG. 5A are comparable to those depicted in Table 2, where the samples with an oxide layer thickness less than 1 μm have a hemispherical emissivity in a comparable range. Simulation results for an FLSP surface with a thick oxide layer on the mounds is included in FIG. 5C. As the oxide layer thickness is increased on the simulated structure, the hemispherical emissivity rapidly increases. The resulting emissivity for the simulation using an oxide layer with a thickness comparable to the measured value from the cross sections in FIG. 4A and FIG. 4B are included in FIG. 5C, with the supercell structure that was used represented in FIG. 5E. FIG. 5D shows a large-area 3D schematic of the periodic arrangement of the supercell presented in FIG. 5E. The simulation results with the oxide layer accurately match the experimentally measured values for these surfaces presented in FIGS. 1A-1C and Table 2.

Further Maximizing Hemispherical Emissivity:

With a better understanding into what causes the substantial increases to the emissivity when FLSP is applied to a metallic surface such as aluminum, it is desirable to understand how the emissivity can be increased further to the maximum value of one. Two factors identified as contributing to the near perfect emissivity are the growth of a (relatively thick) oxide layer and the increase in quasi-periodic surface roughness and structure height. To start these two factors are examined separately.

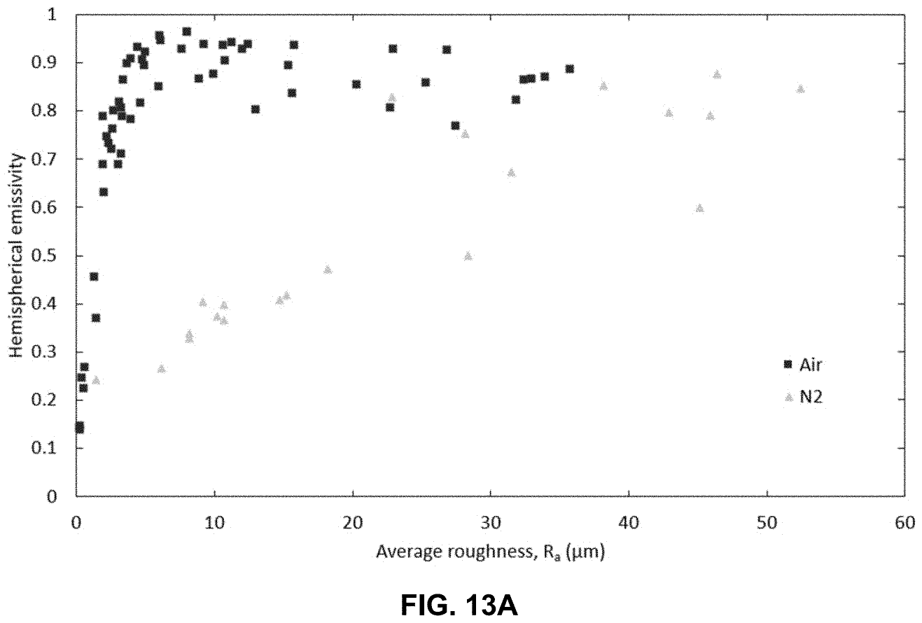

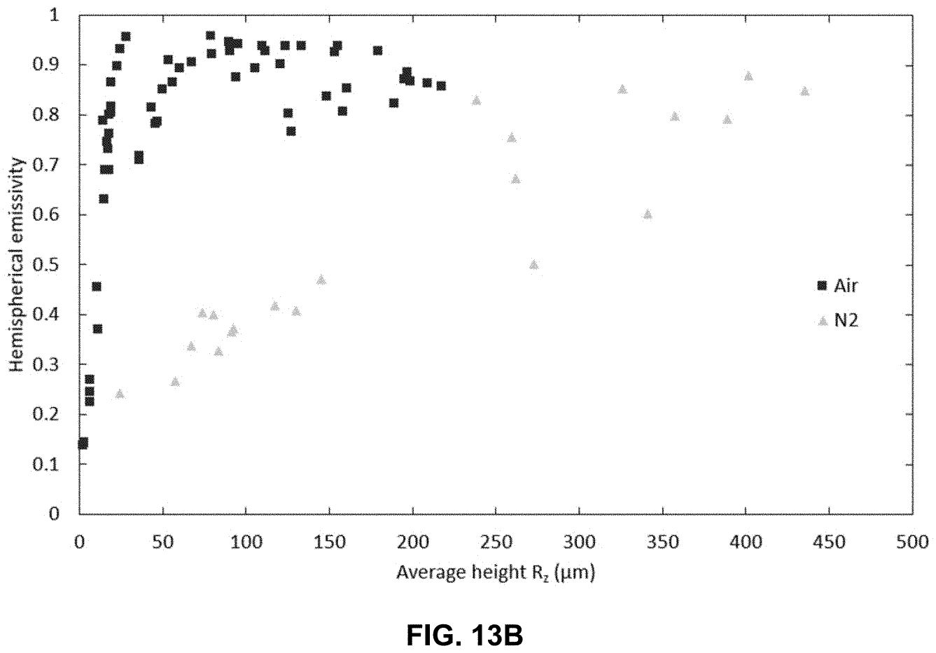

The first case considered is with a negligible oxide layer and changing surface structures. For samples processed in nitrogen the hemispherical emissivity was most strongly influenced by surface roughness and height. For example, increasing peak fluence continues to increase the surface roughness and the hemispherical emissivity until the emissivity levels off with a structure height around 320 μm and an average roughness around 35 μm. These results are illustrated in FIGS. 13A-13B. However, the microstructure demonstrating near-perfect hemispherical emissivity has a structure height around 100 μm and an average roughness of approximately 10 μm when processed in air. This is dramatically lower, approximately one third of the average roughness for the nitrogen sample surface parameters.

Another contributing factor to the increase in emissivity is the growth of a thick oxide layer. First, consider the simpler case of a planar metallic surface, such as planar aluminum, with an oxide layer on top that is flat on the microscale. The resulting hemispherical emissivity of such a system with varying thickness of the oxide layer sch as aluminum oxide is illustrated in FIGS. 12B-12D. A visual depiction of the aluminum oxide/aluminum system can be found in FIG. 12A. The hemispherical emissivity continues to increase until leveling off at −0.8 with around 15 μm of surface oxide. Whereas the surface with a hemispherical emissivity of −0.95, illustrated in Table 2, has an oxide layer thickness of around 8 μm. This is nearly half the thickness of oxide necessary to produce the maximum emissivity based only on oxide layer thickness.

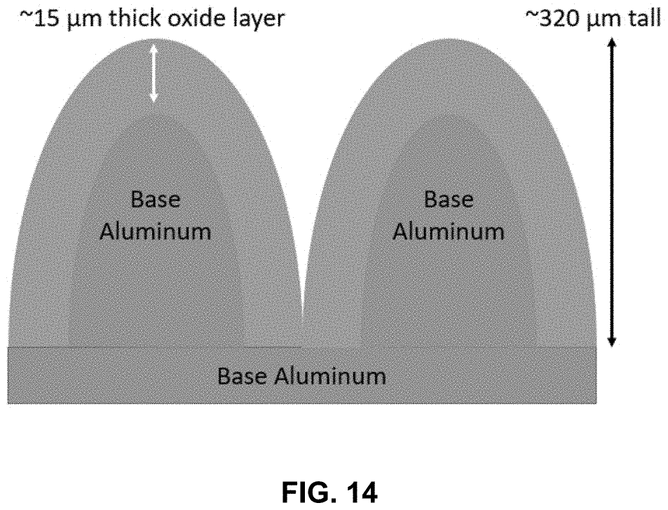

When both surface roughness and oxide layer thickness are considered together and compared to the highest performing sample, the ideal structure to produce a perfect or near-perfect emissivity response is triple the height and has double the oxide layer thickness as the best surface that was discussed previously. Now combining these two observations with the approximately one-to-two base-to-height ratio seen in the near-perfect structures results in the predicted ideal FLSP surface depicted in FIG. 14.

To produce such a surface using FLSP, one place to start is with the laser parameters used for the best performing sample with a fluence of 2.86 J/cm² and a pulse count of 1600. These surfaces have a mound-dominant shape about 90 μm tall with an 8 μm oxide layer. First consider the roughness and height, typically increasing pulse count is a straightforward method to increase height without changing morphology. However, another sample produced at 2.65 J/cm² and 6800 pulses resulted in a structure height of 155 μm. While this is a little short of the 2.86 J/cm² (about 8%) the sample has 4.25 times the pulse count and only produced about half the desired height. If the trend were to continue about 28,900 pulses would be required to produce a structure with the desired height of approximately 320 μm. However, cross sections of high fluence high pulse count structures have shown the redeposition of the oxide layer is no longer uniform (FIGS. 11A-11B) and would likely not produce the desired thickness.

In some aspects, a direct one step laser processing approach for making metallic surfaces having the oxidized-metal-coated structures, according to certain embodiments herein, may not necessarily produce desired results. An alternative method for producing a metallic surface having the oxidized-metal-coated structures, according to certain embodiments herein, comprises first laser-processing a metallic surface, in a nitrogen environment to form microfeatures with desired or preferable dimensions, such as height, height and then performing a second laser-processing step at a substantially lower fluence to coat the mounds in oxide nanoparticles. Literature has shown processing at low fluence (F<0.5 J/cm²) causes the formation of aggregate nanoparticle spheres that consist of exclusively redeposited oxidized nanoparticles having a diameter up to 100 μm making them ideal for this application (see, e.g., Tsubaki, A. T. et al. Formation of aggregated nanoparticle spheres through femtosecond laser surface processing. Appl. Surf. Sci. 419, 778-787 (2017); Zuhlke, C. A., Anderson, T. P. & Alexander, D. R. Fundamentals of layered nanoparticle covered pyramidal structures formed on nickel during femtosecond laser surface interactions. Appl. Surf. Sci. 283, 648-653 (2013)).

Application to Other Materials:

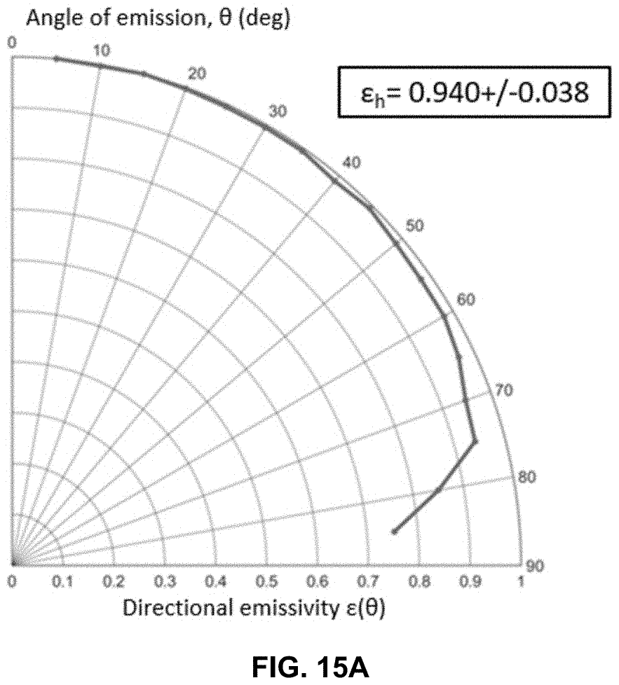

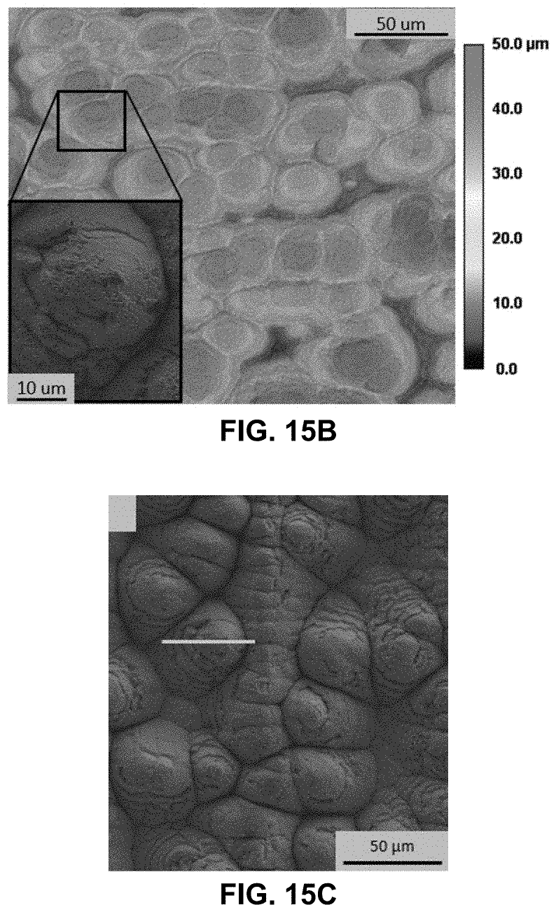

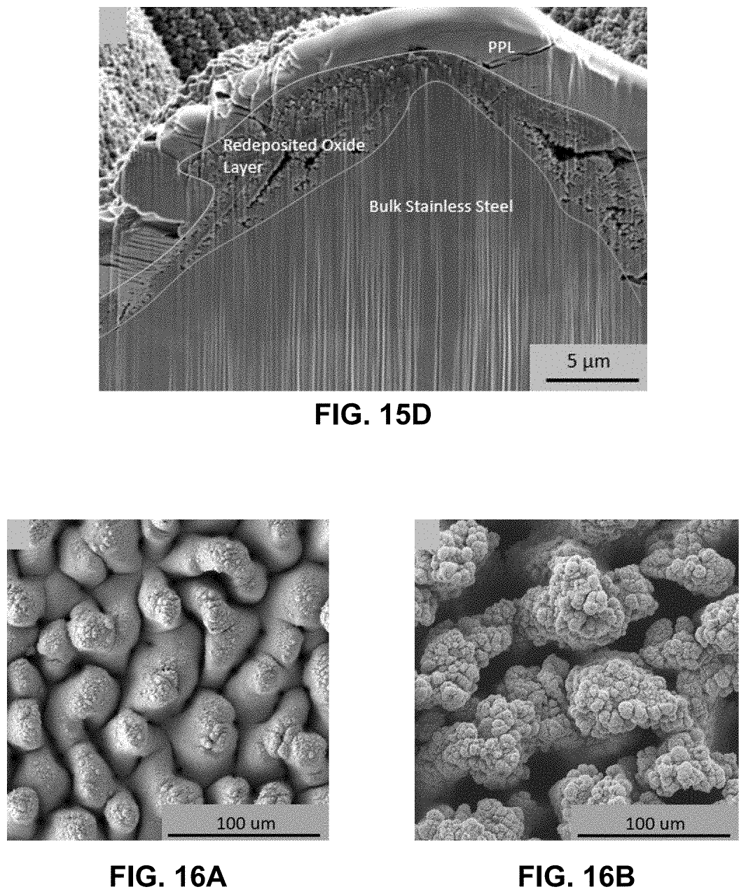

The embodiments, processes, and results described here with respect to aluminum surfaces are transferable to metallic surfaces comprises other metals. For example, similar results to those demonstrated on aluminum have been produced on stainless steel and are illustrated in FIG. 15A. The hemispherical emissivity of the stainless-steel surface was found to be 0.940. While the emissivity values are similar to those produced on aluminum, the laser processing parameters are different. The difference is likely due to the different oxidation dynamics for stainless steel compared to aluminum. As a result, a different approach is useful to produce a thick redeposited oxide layer. At low fluence and very high pulse count, FLSP produces “pyramid” like structures called such because of their approximately 1 to 1 aspect ratio. Studies have shown these structures to be the result of many layers of redeposited nanoparticles that build-up on top of the base microstructure (see: Zuhlke, C. A., Anderson, T. P. & Alexander, D. R. Fundamentals of layered nanoparticle covered pyramidal structures formed on nickel during femtosecond laser surface interactions. Appl. Surf. Sci. 283, 648-653 (2013).

For these studies, mirror finished stainless-steel 304 (SS304) was used. To maximize the emissivity, the processing parameters were varied in a range of laser fluence values from 0.005 to 2.5 J/cm², with a pulse count between 1,800 and 50,000. The sample resulting in the highest emissivity was selected. Then, pulse count was varied in steps of approximately 10% until reaching a value of about 50% above and below the starting value. Again, the processing parameters from the best performing sample was chosen. Next, fluence was varied in steps to reach a value of about 20% above and below the starting fluence to find the best emissivity results. The maximized emissivity was produced using a fluence of about 0.008 J/cm² and about 23,000 pulses. The microscale surface features are typical of pyramids and include structures with widths of approximately 30 to 40 μm and heights in the range of 40 to 50 μm with an average roughness of 7 μm. However, there is significant variation in size from pyramid to pyramid as visible in the 3D profile of the LSCM image included in FIG. 15B. The high emissivity suggests a relative thick layer of oxidized nanoparticles. SS304 is approximately 70% Iron, 20% chromium and 10% nickel leading to a primarily iron oxide nanoparticle layer.

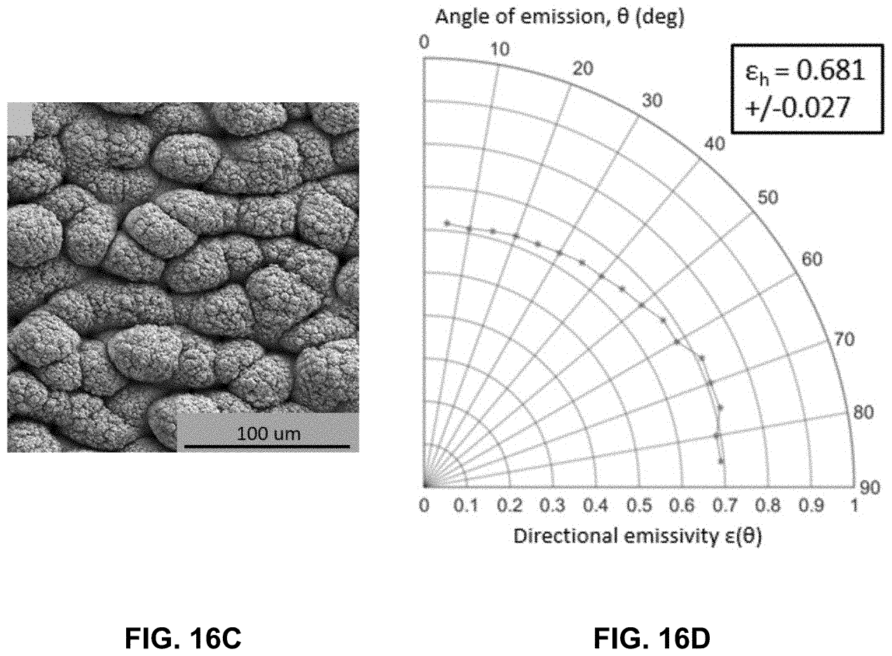

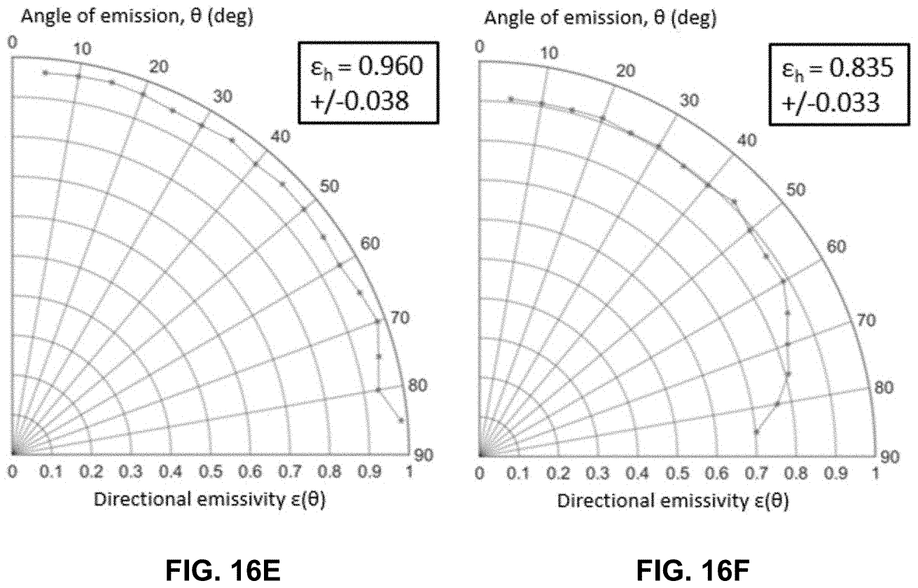

FLSP can easily be applied to nearly any material, including, e.g., metals, dielectrics, semiconductors, ceramics and polymers. The SEM images included in FIGS. 16A-16C are for FLSP applied to silver, titanium, and copper, each with a different set of laser processing parameters. For these materials, the maximum increase in emissivity was not found using the rigorous process used for aluminum. Instead, these initial results are included as a proof of concept that FLSP can be used to produce high emissivity surfaces on many other materials. The data corresponds well with previous findings; quasi-periodic surface roughness and a redeposited oxide layer are important factors contributing to the increase in emissivity. All three of the metals presented here have a significant increase in hemispherical emissivity from that of the unprocessed metal when FLSP is applied (see Table 3).

TABLE 3
The hemispherical emissivity and electronegativities
of aluminum, titanium, copper, and silver.

| Element | Aluminum | Silver | Titanium | Copper |
|---|---|---|---|---|
| Hemispherical | 0.09 | 0.02 | 0.10 | 0.07 |
| Emissivity of | | | | |
| Unprocessed | | | | |
| Metal [35] | | | | |
| Hemispherical | 0.945 +/− | 0.681 +/− | 0.960 +/− | 0.835 +/− |
| Emissivity | 0.038 | 0.027 | 0.038 | 0.033 |
| after processing* | | | | |

*Silver, titanium, and copper results are not fully optimized.

Additional Discussion:

FLSP is an emerging advanced manufacturing technique that can be used to functionalize aluminum surfaces to have broadband omnidirectional hemispherical emissivity close to the absolute maximum value of unity in the spectral range from 7.5 to 14 μm. In addition, the FLSP-processed metallic surface having the oxidized-metal-coated structures, according to certain embodiments herein, have high emissivity even at glancing angles, which is very challenging to be achieved with coatings, metamaterials or other perfect emission structures. Extensive experimental results along with accurate theoretical modeling demonstrate that there are two key contributing factors to the increase in emissivity; microscale surface roughness and a thick oxide layer that forms when FLSP is applied using the presented processing parameters. Processing in a nitrogen atmosphere results in an increase in surface roughness compared to processing in an air environment using similar processing parameters. However, the thick oxide layer on samples processed in air results in higher emissivity values than samples processed in nitrogen. Therefore, processing in oxygen-containing environments/gases such as air yields surfaces better optimized for potential applications, in some aspects disclosed herein. The use of an acid etch technique to uniformly decrease the thicknesses of the oxide layer without affecting the underlying structure morphology demonstrates the key role that the oxide layer thickness plays in the high emissivity. The best performing FLSP-processed metallic surface having the oxidized-metal-coated structures, according to certain embodiments herein, have higher omnidirectional emissivity values than current coatings or metamaterials. They also have additional important benefits that include significantly wider bandwidth and lower fabrication complexity than metamaterials, as well as greater permanency and durability compared to coatings, which is a key property for operation in harsh environments. With the use of industrial high repetition rate ultrashort pulse lasers that are available today, this functionalization technique represents a quick, low-cost, and large-scale fabrication technique without the added weight, hazard of toxicity, and long curing time required in many comparable technologies. The presented FLSP surfaces are ideal for thermal management applications, such as passive radiative cooling, thermophotovoltaics, thermal management of satellites, and other space applications.

### Non-Exhaustive Examples and Embodiments of Materials, Features, Steps of Methods and Materials According to Certain Aspects

Femtosecond laser surface processing. For laser processing the samples, the experimental setup consisted of a femtosecond laser system, beam delivery and focusing optics, motorized 3D stages, sample environmental chamber, and a computer to control the system (See references for diagram in Tsubaki, A. T. et al. Formation of aggregated nanoparticle spheres through femtosecond laser surface processing. Appl. Surf. Sci. 419, 778-787 (2017), and Tsubaki, A. et al. Oxide layer reduction and formation of an aluminum nitride surface layer during femtosecond laser surface processing of aluminum in nitrogen-rich gases. Laser-based Micro-Nanoprocessing XIII 22 (2019) doi:10.1117/12.2508812). For the samples processed in different background gases, the surface processing was completed in a vacuum chamber attached to the motorized stages with a flow rate of 20-25 scfh of the respective gas at atmospheric pressure. Laser input power was adjusted to account for 8.2% loss from the input window of this chamber. The best performing samples, as well as those used in the acid etching were processed in open air without the vacuum chamber. The femtosecond laser systems used were titanium (Ti):sapphire based amplified systems (a Coherent Inc. Legend Elite Duo and a Coherent Inc. Astrella) generating 35 fs pulses, with a central wavelength of 800 nm, a pulse repetition rate of 1 kHz, and a maximum output pulse energy of 10 mJ and 6 mJ respectively. The laser spot size on the sample was measured by placing a beam profiler with the imaging plane at the same location where the sample is located during processing. The spot size, raster scanning parameters (pitch and velocity), and pulse energy, measured using a thermal pile detector, were used to calculate the peak fluence (the energy per unit area at the peak of the Gaussian) and pulse count. The sample material used was mirror polished aluminum alloy 6061. Before the laser processing, the samples were cleaned in an ultrasonic bath in a 2-step process consisting of a 15-minute ethanol bath followed by a 15-minute deionized water bath. Immediately before each sample was placed in the chamber it was wetted with ethanol and blown dry with nitrogen to remove any surface contamination. After processing, emissivity was evaluated, and the surface structure was characterized by SEM (FEI Quanta 200) and LSCM (Keyence VK-X200K). The LSCM was used to quantify the structure height and average roughness. It will be appreciated by one of skill in the art that other pulsed laser system or pulsed laser beams generated by other systems and optionally not necessarily characterized as “femtosecond” may be useful in methods disclosed herein and capable of forming oxidized-metal-coated structures disclosed herein.

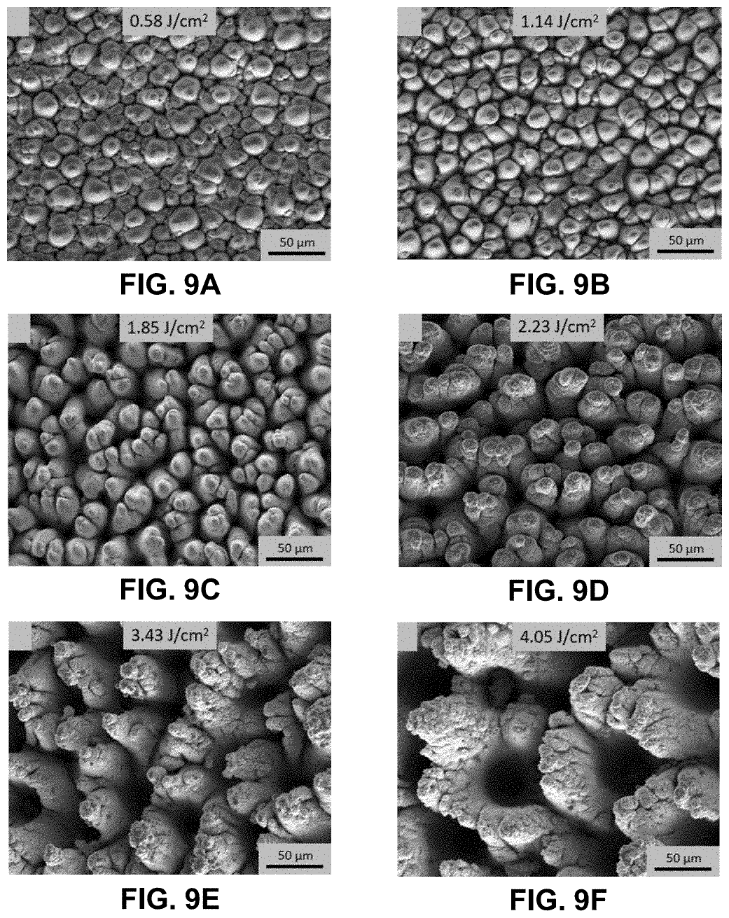

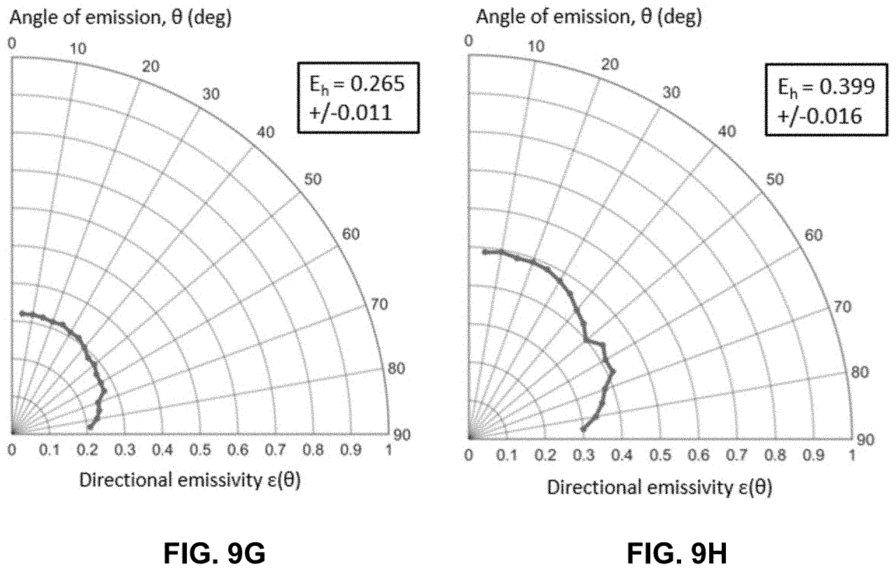

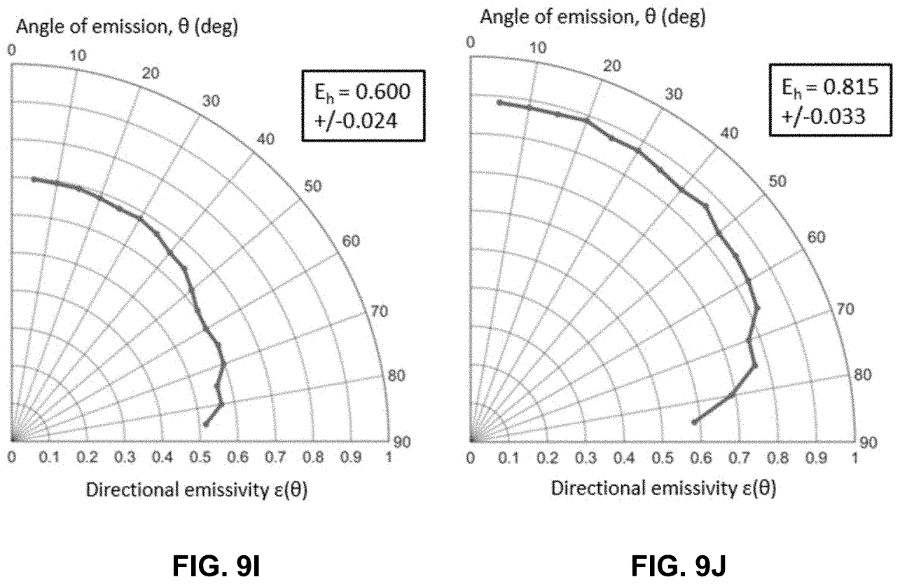

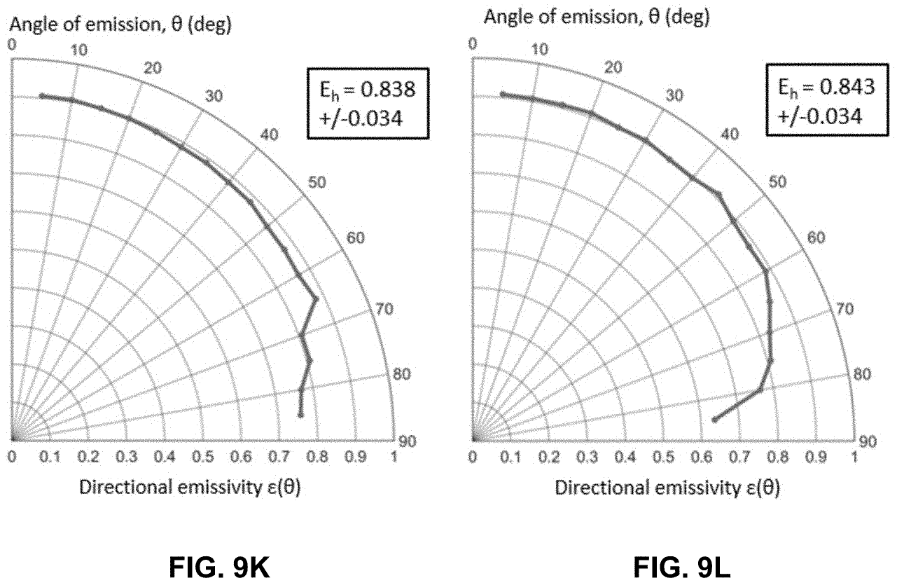

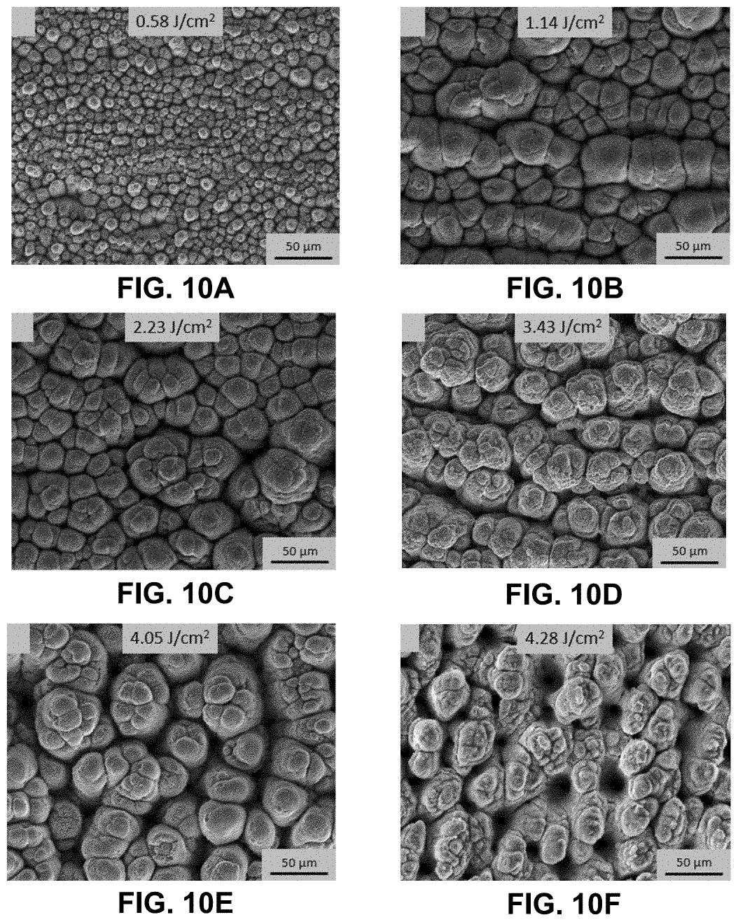

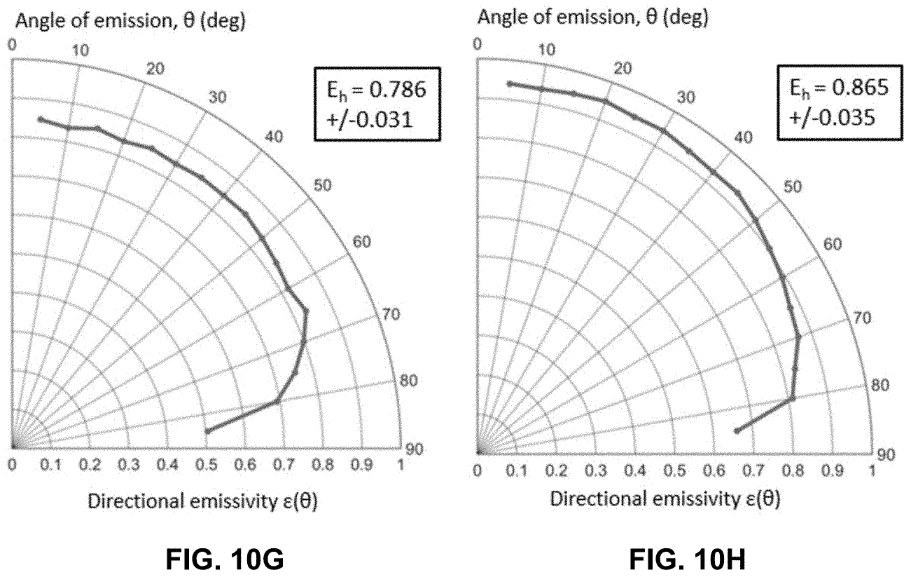

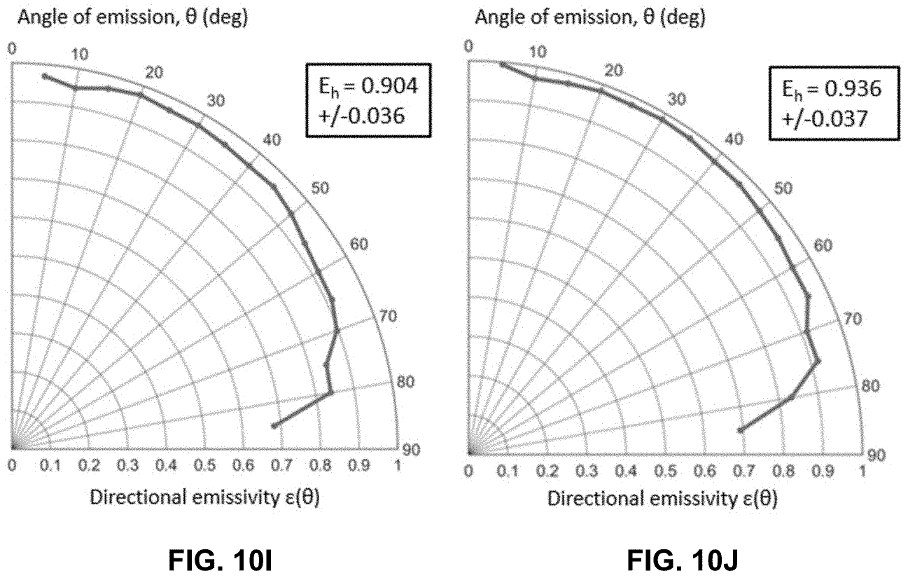

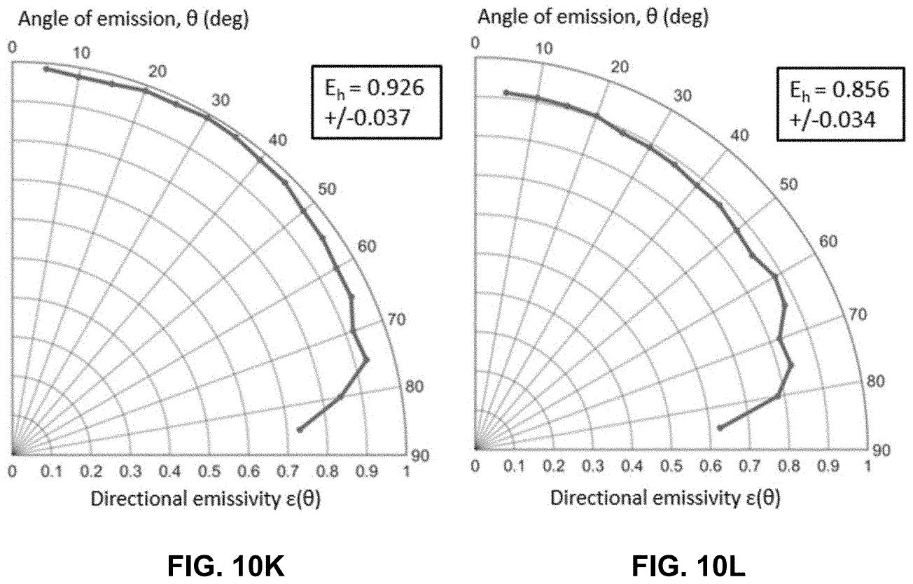

Optimizing emissivity. In order to systematically study the effects that different processing parameters and background environments have on emissivity, an iterative process was used to find the processing parameters that lead to the maximum hemispherical emissivity. With initial experiments on aluminum that included studies on a wide range of surface structures, it was found that mound-like structures resulted in the highest emissivity values. For these experiments, samples were first produced using a range of laser fluence values from 0.38 to 4.85 J/cm², with a constant pulse count of around 1900. This process was completed in controlled atmospheres of air and nitrogen as well as an open-air environment. A representative range of resulting surface morphologies and the properties of the surfaces produced in the controlled environments can be seen in FIGS. 9A-9L and FIGS. 10A-10L. To achieve the maximize emissivity, the processing parameters were varied slightly around their initial values for the best performing sample. First, pulse count was varied in steps of approximately 10% until reaching a value of about 50% above and below the starting value. Again, the processing parameters from best performing sample was chosen. Next, fluence was varied in steps to reach a value of about 20% above and below the starting fluence in order to find the best results. Using this iterative process, it was found that optimal results could be produced using a fluence between 2.6 and 2.8 J/cm² and a pulse count of 1600 to 2000.

Measuring directional and hemispherical emissivity. Here, the hemispherical emissivity is calculated from experimentally measured directional emissivity values using conservation of energy and the Stefan-Boltzmann law (Eqs. 5 and 6, below). A thermal imaging camera (FLIR A655sc) and a sample with a known directional emissivity as the calibrated source were utilized. To measure the emissivity, the temperature of the known sample and the sample of interest are heated to the same temperature, 50° C. This process helps minimize the contribution of background radiation as well as ensure the samples radiate equal amounts of energy. The heating effect is minimal to the emissivity. The thermal imaging camera operates over a spectral range from 7.5 to 14 μm and was used to evaluate the directional emissivity from 0 (normal to the surface) to 85 degrees. The directional emissivity values were used to calculate the hemispherical emissivity using Eq. 7, below.

Acid etching technique. In order to better understand the role that the oxide layer, introduced by the FLSP process, plays on the resulting emissivity, samples with maximum hemispherical emissivity were etched with an aqueous acid solution consisting of either 20 g/l (2%) or 100 g/l (10%) chromic acid and an additional 35 ml/l of 85% phosphoric acid solution. During the acid etching the samples were heated to between 82° C. and 99° C. for the specified amount of time. This solution was chosen because it removes aluminum oxide without damaging the underlying metal. Twelve samples from the same batch were used for these studies. Two samples were not etched to use as controls. Six of the samples were etched in a solution of 2% chromic acid in sets of two for different lengths of time at 20, 60, and 100 minutes, respectively. The last two sets of samples were etched in a 10% Chromic acid solution for 60 and 120 minutes, respectively. After etching the surface morphology and emissivity were re-evaluated. Surface structures were cross-sectioned using FIB milling and then characterized by SEM and EDS (FEI Helios NanoLab 660).

Theoretical simulations. The reflectivity spectra of the presented FLSP surfaces was simulated for different incident angle plane waves using the RF module of COMSOL Multiphysics. We utilized periodic boundary conditions surrounding a supercell composed of two different mounds with and without an oxide layer on top. The absorption spectra of the structure for different incident angles were computed, which is equivalent to the emission spectrum for different emission angles at thermal equilibrium due to Kirchhoff's law of thermal radiation. The mounds have similar dimensions to the experimentally produced samples. The aluminum oxide layer thickness that was used is also comparable to the experimental measured values. MATLAB was used to post process the COMSOL raw data and to average the emissivity results for different angle and wavelength values with the goal to calculate the hemispherical emissivity for a variety of different surfaces. Further explanation of the used theoretical technique is below.

Statistical Information:

The uncertainty in hemispherical emissivity values measured using the thermal imaging camera (TIC) based technique, described below, is accounted to two causes. First, for most samples, because the directional emissivity is consistent across all angles with only a slight decrease after 65 degrees, the geometric error caused by approximating the value of the integral to calculate hemispherical emissivity from the directional measurements is less than 2%. The remaining uncertainty is accounted for in the 2% error from thermal camera as stated by the manufacturer. The reflection-based instrument (Surface Optics SOC-100), has an uncertainty of 1% overall for hemispherical and directional emissivity measurements as quoted by the manufacturer. The maximum hemispherical emissivity value reported is the average of 24 measurements, two per each of the 12 samples produced in six batches using two laser systems at three different times. The standard deviation of the 24 measurements is also reported.

The reported measured surface roughness parameters are the average and standard deviation from the LSCM scans. For the background gas experiment, three LSCM scans from different locations on each sample were used. For the acid etching experiment, four LSCM scans were used, two scans per sample at each given etching parameter. For each scanned area, the average roughness (Ra) was measured over the entire scanned area. However, the average height was the average of the maximum height (R_{z}) measurement for ten subset areas within each scanned area.

Additional Technical Information:

Emissivity is the dimensionless ratio used to describe how efficiently an absorbing surface emits thermal energy, where zero represents a perfect reflector and one represents a perfect emitter. The spectral directional emissivity describes the emissivity of a surface at a particular wavelength, orientation, and temperature, ε(λ, θ, φ, T). The spectral hemispherical emissivity is computed by integrating the spectral directional emissivity over all emission angles at a particular fixed wavelength and temperature, ε(λ, T). Lastly, the total hemispherical emissivity is computed by integrating the spectral directional emissivity over all emission directions and in the wavelength range of interest but for a fixed temperature, ε(T).

Polished metals usually have a low hemispherical emissivity with a higher directional emissivity at low angles relative to the surface normal. When roughness or oxidation is taken into account, the emissivity is usually increased. Generally, the increase of surface roughness leads to an increase in emissivity independent of the wavelength. The increase in emissivity caused by roughness is typically illustrated by the optical roughness metric, i.e., the ratio of wavelength divided by the surface roughness. If this ratio is small (less than 0.2), the surface can be described as optically smooth and its properties approach that of an ideal smooth surface with emissivity computed by theory using Maxwell's equations. If this ratio is large, then a geometric optics approach or full-wave electromagnetic simulations must be utilized to take into account the surface morphology. Emissivity is also a function of the surface temperature, wavelength, and observation angle. The effect of these properties can vary greatly depending on the material.

In metals the effect of temperature on emissivity is primarily dependent on the temperature dependent resistivity of the material. The Hagen-Rubens relation shows that for most materials the emissivity is proportional to the square root of resistivity, for sufficiently short wavelengths. Specifically, for aluminum, experimental data has shown that over the temperature range of 0° C. to 400° C. the resistivity can be approximated by a linear equation. The resulting effect on emissivity is weak and causes a variance of approximately 0.006 to 0.008 per hundred degrees Celsius. Since this value is so small over such a wide temperature range, the effect of temperature on emissivity is ignored here. For wavelengths longer than 1 μm the directional emissivity of metals tends to increase at large angles, leading to a “flat top” profile (an example of this effect is demonstrated in FIG. 7).

For dielectric materials like metal oxides, temperature typically has even less effect on emissivity than for metals. The spectral properties of dielectrics change very slowly with temperature since the refractive index is not a strong function of temperature. For dielectrics, the most significant effect of temperature is related to measuring their thermal radiation power because the wavelength shift in the blackbody radiation distribution needs to be considered. The spectral range considered for this paper corresponds to the atmospheric window from 7.5 to 14 μm or peak blackbody radiation from −66° C. to 110° C. Unlike metals, in dielectrics the directional emissivity tends to decrease at large angles. However, this can vary greatly with surface roughness.

The FLSP-processed metallic surface having the oxidized-metal-coated structures, according to certain embodiments herein, are a combination of dielectric and metal materials and both must be considered for understanding the increase in emissivity for the processed surfaces. The base aluminum is pure metal and the surface oxide is a dielectric. The thickness of the oxide layer varies greatly depending on the processing parameters.

Theoretical evaluation of total hemispherical emissivity of a surface: In order to provide the appropriate theoretical background on the different emissivity notations, a mathematical representation is included here. A diagram showing the measurement setup is illustrated in FIG. 6. The spectral directional emissivity, ε(θ, φ, λ, T) of an opaque material (T=0) is obtained in accordance with Kirchhoff's Law of thermal equilibrium shown in Eq. 1:

ε(θ,φ,λ,T)=α(θ,φ,λ,T)=1−ρ(θ,φ,λ,T), (1)

where α is the absorption and ρ is the reflectivity. Most methods for calculating the emissivity of a surface are derived from these equations by computing the reflectance and assuming no dependence on the solid angle φ, which means the spectral directional emissivity is assumed to be independent of the sample rotation. The spectral hemispherical emissivity, ε(λ, T), can be calculated from the spectral directional emissivity by using the following formula:

ε(λ,T)=2∫₀^{π/2}ε(θ,λ,T)sin θ cos θdθ (2)

The total hemispherical emissivity, ε(T), is obtained via integration over the Planck distribution (P):

$$ɛ ( T ) = \frac{{\int }_{0}^{∞} ɛ ( λ , T ) P ( λ , T ) d λ}{{\int }_{0}^{∞} P ( λ , T ) d λ} \qquad ( 3 )$$

P is given by Eq. 4:

$$P ( λ , T ) = \frac{8 π h c}{{λ}^{5} {e}^{\frac{hc}{λ kT} - 1}} , \qquad ( 4 )$$

where h is Planck's constant, k is the Boltzmann constant, c is the speed of light, λ is the wavelength, and T is the temperature. It is important to note that the integral in Eq. (3) is evaluated from 0 to infinity. However, experimentally it is not possible to make measurements that cover all wavelengths and, therefore, a finite wavelength range must be used.

Measuring directional and hemispherical emissivity: Here, the hemispherical emissivity is calculated from the experimentally measured directional emissivity by using conservation of energy and the Stefan-Boltzmann law (Eq. 5 and 6). Utilizing the measured temperature of the calibrated source and its emissivity, the temperature and thus the energy of the detector can be found. From here, the directional emissivity of the unknown sample can be calculated as a ratio of the temperature of the sample to that of the detector minus some small background contribution (see Eq. 5). The energies (E) of the detector, sample, and background are calculated from their temperatures by using the Stefan-Boltzmann law (see Eq. 6):

E_{detector}=εE_{Sample}+(1−ε)E_{background}, (5)

E=σT⁴. (6)

Testing was performed to show that the sample reference direction had no effect on the emissivity (φ) (see FIG. 6 for a depiction of the emissivity measurement setup). The hemispherical emissivity Eₕ is calculated by using Eq. 7. Note that the only difference between Eq. 7 and Eq. 2, the equation for calculating the spectral hemispherical emissivity, is the lack of a spectral dependence in Eq. 7.

Eₕ=ε(T)=2∫₀^{π/2}ε(θ,T)sin θ cos θdθ (7)

However, experimentally measurements are made at discrete angles (not as a continuous function) and the integral described in Eq. 7 must be approximated. For the approximation two methods are employed, the rectangular and trapezoidal integration approximation, and the average between them is used. The rectangular approximation has a tendency to overestimate the area of a concave down curve and underestimate concave up, whereas the trapezoidal approximation has the opposite effect. The difference in these two estimations is used to find the geometric uncertainty in the hemispherical emissivity.

Verifying method for measuring emissivity: Two approaches were used to verify the validity of the presented technique for measuring emissivity. First, the hemispherical emissivity of three pieces of mirror polish aluminum 6061 with an average surface roughness of less than 0.5 μm was measured three times and averaged. The resulting measured values are reported in FIG. 7. They are typical of mirror polished aluminum and found to be in good agreement with experimental results from the literature ranging between 0.04 to 0.09. Simulation results for the emissivity of a flat aluminum surface as well as theoretical values calculated are also included in FIG. 7. The 23% difference in hemispherical emissivity between the measured and theoretical values is likely a result of the native oxide layer formed on all aluminum surfaces, as well as the surface roughness. Both these effects are not included in this theoretical modeling.

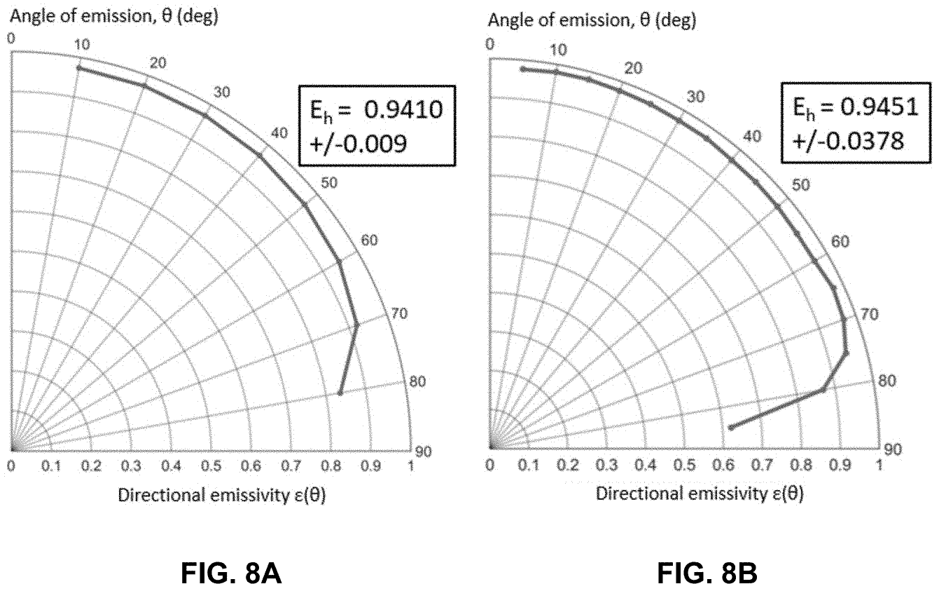

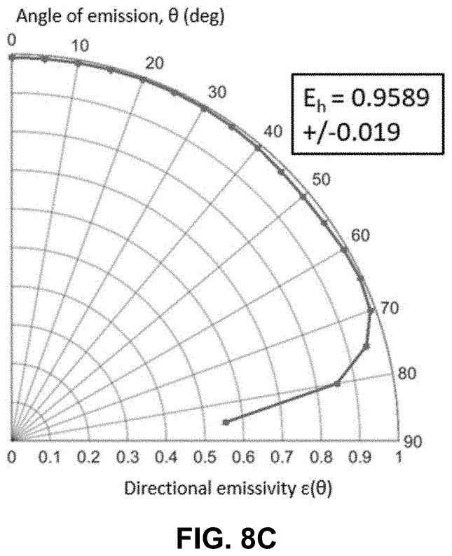

In addition, the emissivity of the best performing sample (described above (see FIGS. 1A-1C)) was measured using a reflection-based instrument (Surface Optics SOC-100), which provides the reflection coefficient as a function of wavelength. The results were compared with our TIC testing method and are illustrated in FIGS. 8A-8C. The difference between the measured hemispherical emissivity for the two techniques is negligible and less than 0.5%.

Extended data: As noted above, directional and hemispherical emissivity measurements and SEM images for additional surfaces processed with varied fluence and processed in nitrogen and air are included in FIGS. 9A-9L and FIGS. 10A-10L, respectively.

Theoretical simulations: Simulations of an ideal polished flat aluminum surface can be found in FIG. 7 and agree with experimental and analytical results found in the relevant literature. The emissivity of aluminum with an oxide layer on top was also simulated to further verify the theoretical model. Polished aluminum can be anodized to grow a thick oxide layer on its surface. Experimental data shows that the hemispherical emissivity of the aluminum/aluminum-oxide system increases rapidly until the oxide thickness of about 15 μm, where it levels out, asymptotically approaching ˜0.85 for larger oxide thicknesses. Simulations, illustrated in FIGS. 12A-12D, were performed for 5, 15, and 20 μm oxide layer thickness and agree with the experimental data reported in the literature.

Reference is also made to U.S. Provisional Patent Application No. 63/631,289, titled “MULTI-MATERIAL, MULTI-LAYERED FEMTOSECOND LASER SURFACE PROCESSING,” and filed on May 28, 2020, which is incorporated by reference herein. In certain embodiments, the multi-material concept can be used to increase the emissivity on some materials. For example, aluminum can be overlaid on copper prior to processing and will result in higher-emissivity copper surfaces after processing than if the aluminum was not used.

All references, including publications, patent applications, and patents, cited herein are hereby incorporated by reference to the same extent as if each reference were individually and specifically indicated to be incorporated by reference and were set forth in its entirety herein.

It should be understood that the arrangement of components discussed and/or illustrated herein are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

### Statements Regarding Incorporation by Reference and Variations

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. When a compound is described herein such that a particular isomer, enantiomer or diastereomer of the compound is not specified, for example, in a formula or in a chemical name, that description is intended to include each isomers and enantiomer of the compound described individual or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Methods for making such isotopic variants are known in the art. Specific names of compounds are intended to be exemplary, as it is known that one of ordinary skill in the art can name the same compounds differently.

Every device, system, material, component, combination of features, and method described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

We claim:

1. A method for laser-processing a metallic surface to produce a functionalized metallic surface, the method comprising:
providing a substrate having the metallic surface;
applying a pulsed laser beam with a controlled fluence to a region of the metallic surface in an environment containing oxygen, wherein metal material in the region of the metallic surface ablates due to the applied pulsed laser beam and wherein at least a portion of the ablated metal material oxidizes and redeposits on the metallic surface to produce one or more oxidized-metal-coated structures;
wherein the metallic surface having the one or more oxidized-metal-coated structures is the functionalized metallic surface.

2. The method of claim 1, wherein the functionalized metallic surface has a higher hemispherical emissivity than the metallic surface free of the oxidized-metal-coated structures and prior to applying the pulsed laser beam under otherwise identical conditions.

3. The method of claim 1, wherein the functionalized metallic surface has a 15% to 1200% higher hemispherical emissivity than the metallic surface free of the oxidized-metal-coated structures and prior to applying the pulsed laser beam under otherwise identical conditions.

4. The method of claim 1, wherein the functionalized metallic surface is characterized by a hemispherical emissivity of at least 0.85 over a wavelength range selected from the range of 0.2 μm to 20 μm and at a temperature selected from the range of −125° C. to 2,700° C.

5. The method of claim 1, wherein the functionalized metallic surface is characterized by broadband omni-directional hemispherical emissivity

6. The method of claim 4, wherein the metal material comprises aluminum, iron, silver, titanium, copper, or a combination of these.

7. The method of claim 1, wherein pulsed laser beam is a femtosecond laser beam and the step of applying is a step of applying a femtosecond laser surface processing (FLSP) with the controlled fluence to the region of the metallic surface.

8. The method of claim 7, wherein the applying FLSP with a controlled fluence includes applying a series of laser pulses having a fluence of between 0.3 J/cm² to 5.0 J/cm².

9. The method of claim 8, wherein the fluence is between 2.5 J/cm² to 3.0 J/cm².

10. The method of claim 7, wherein each of the pulses has a same wavelength of between 100 nm and about 21,000 nm.

11. The method of claim 10, wherein each of the pulses has a same wavelength of 800 nm.

12. The method of claim 1, wherein the environment containing oxygen comprises air.

13. The method of claim 1, wherein the step of applying comprises a first applying step and a second applying step;
wherein the first applying step comprises applying a first pulsed laser beam with a first controlled fluence to the region of the metallic surface in an environment free of oxygen; wherein a plurality of microfeatures are formed in the metallic surface in the region during the first applying step;
wherein the second applying step comprises applying a second pulsed laser beam with a second controlled fluence to the region of the metallic surface in an environment comprising oxygen; and wherein the metal material in the region of the metallic surface ablates due to the applied second pulsed laser beam and wherein at least a portion of the ablated metal material oxidizes and redeposits on the plurality of microfeatures to produce one or more oxidized-metal-coated structures.

14. The method of claim 13, wherein the second controlled fluence is less than the first controlled fluence.

15. A functionalized metallic surface that exhibits substantially broadband omni-directional hemispherical emissivity, the metallic surface comprising multiple oxidized-metal-coated structures produced by femtosecond laser surface processing (FLSP) with a controlled fluence.

16. The functionalized metallic surface of claim 11, wherein each of the one or more oxidized-metal-coated structures has an oxide metal layer having a thickness of between 0.1 μm to 100 μm or greater.

17. The functionalized metallic surface of claim 11, wherein each of the one or more oxidized-metal-coated structures has height of between 5.0 μm to 1,000 μm and/or a structural diameter of between 5.0 μm to 1,000 μm.

18. The functionalized metallic surface of claim 16, wherein each of the one or more oxidized-metal-coated structures is a microfeature having a mound, pyramid, peak, spike, or pillar cross-sectional outline.

19. The functionalized metallic surface of claim 11, wherein the functionalized metallic surface has a 15% to 1200% higher hemispherical emissivity than a planar metallic surface free of the oxidized-metal-coated structures under otherwise identical conditions.

20. The functionalized metallic surface of claim 11, wherein the functionalized metallic surface is characterized by a hemispherical emissivity of at least 0.85 over a wavelength range selected from the range of 0.2 μm to 20 μm and at a temperature selected from the range of −125° C. to 2,700° C.
